(19) United States
(12) Patent Application Publication
(10) Pub. No.: US 2026/0343856 A1
(43) Pub. Date: Oct. 29, 2026

(54) SEMICONDUCTOR MEMORY DEVICE INCLUDING SELF-ALIGNED SUPPORTER HOLES

(71) Applicant: Samsung Electronics Co., Ltd., Suwon-si (KR)

(72) Inventors: Seongtak CHO, Suwon-si (KR); Donghyung KIM, Suwon-Si (KR); Yong Kwan KIM, Suwon-si (KR); Inwoo KIM, Suwon-si (KR); Hui-Jung KIM, Suwon-si (KR); Gyusoup LEE, Suwon-si (KR); Sangho LEE, Suwon-si (KR); Hongjun LEE, Suwon-si (KR)

(21) Appl. No.: 19/404,128

(22) Filed: Dec. 1, 2025

(30) Foreign Application Priority Data
Apr. 24, 2025 (KR) 10-2025-0054011

(51) Int. Cl. H10B 12/00; H10D 1/68; H10D 1/00

(52) U.S. Cl. CPC H10B 12/315; H10B 12/318; H10B 12/34; H10D 1/692; H10D 1/041

(57) ABSTRACT

According to some embodiments of the present disclosure, a semiconductor memory device includes a substrate, a plurality of lower electrodes each including a first portion disposed on the substrate and extending in a first direction perpendicular to an upper surface of the substrate, and a second portion stacked on the first portion and extending in the first direction, a first supporter pattern surrounding a sidewall of the first portion of each of the plurality of lower electrodes and including a plurality of first supporter holes, a second supporter pattern surrounding a sidewall of the second portion of each of the plurality of lower electrodes and including a plurality of second supporter holes, a dielectric layer disposed on the plurality of lower electrodes, the first supporter pattern, and the second supporter pattern, and an upper electrode covering the dielectric layer.

### CROSS-REFERENCE TO RELATED APPLICATION

This application claims priority under 35 U.S.C. §119 to Korean Patent Applications No. 10-2025-0054011, filed in the Korean Intellectual Property Office on Apr. 24, 2025, the entire contents of which are hereby incorporated by reference.

### BACKGROUND

With continued advances in semiconductor technology, semiconductor devices are becoming more highly integrated and miniaturized, and consequently, individual components of the devices are also trending toward smaller dimensions. In particular, in memory devices such as DRAM, it is desirable to form a lower electrode of a capacitor with a high aspect ratio in order to secure sufficient capacitance. A supporter capable of supporting the lower electrode is generally required to secure structural stability of the high-aspect-ratio lower electrode and to improve process reliability.

As the height of the lower electrode increases, methods of forming the lower electrode and the supporter therefor in multiple steps are being considered.

### SUMMARY

An aspect of the present disclosure provides a semiconductor memory device that includes self-aligned supporter holes patterned by a self-alignment technique.

According to some embodiments of the present disclosure, a semiconductor memory device includes a substrate, a plurality of lower electrodes each including a first portion disposed on the substrate and extending in a first direction perpendicular to an upper surface of the substrate, and a second portion stacked on the first portion and extending in the first direction, a first supporter pattern surrounding a sidewall of the first portion of each of the plurality of lower electrodes and including a plurality of first supporter holes, a second supporter pattern surrounding a sidewall of the second portion of each of the plurality of lower electrodes and including a plurality of second supporter holes, a dielectric layer disposed on the plurality of lower electrodes, the first supporter pattern, and the second supporter pattern, and an upper electrode covering the dielectric layer. The second portion overlaps at least part of the first portion in the first direction and is offset from the first portion in a second direction perpendicular to the first direction.

According to some embodiments of the present disclosure, a semiconductor memory device includes a substrate including an active pattern, a plurality of conductive patterns disposed on the active pattern, a plurality of lower electrodes respectively electrically connected to the plurality of conductive patterns, a plurality of supporter patterns supporting the plurality of lower electrodes, a dielectric layer on the plurality of lower electrodes and the plurality of supporter patterns, and an upper electrode covering the dielectric layer. Each of the plurality of lower electrodes may include a first portion extending in a first direction perpendicular to an upper surface of the substrate and a second portion stacked on the first portion and extending in the first direction. The plurality of supporter patterns includes a first supporter pattern surrounding a sidewall of the first portion and including a plurality of first supporter holes, and a second supporter pattern surrounding a sidewall of the second portion and including a plurality of second supporter holes. Each second portion overlaps a corresponding first portion in the first direction and is offset from the first portion by a first distance in a second direction perpendicular to the first direction, and each of the plurality of second supporter holes is offset from a corresponding one of the plurality of first supporter holes by the first distance in the second direction.

According to some embodiments of the present disclosure, a semiconductor memory device includes a substrate, a plurality of lower electrodes each including a first portion disposed on the substrate and extending in a first direction perpendicular to an upper surface of the substrate, and a second portion stacked on the first portion and extending in the first direction, a first supporter pattern including a plurality of first supporter layers in which a first supporter-hole pattern including a plurality of first supporter holes aligned and spaced in the first direction is formed, the first supporter pattern surrounding a sidewall of the first portion of each of the plurality of lower electrodes, a second supporter pattern including a plurality of second supporter layers in which a second supporter-hole pattern including a plurality of second supporter holes aligned and spaced in the first direction is formed, the second supporter pattern surrounding a sidewall of the second portion of each of the plurality of lower electrodes, a dielectric layer on the plurality of lower electrodes, the first supporter pattern, and the second supporter pattern, and an upper electrode on the dielectric layer. The second portion overlaps part of the first portion in the first direction and is offset from the first portion in a second direction perpendicular to the first direction, and the first supporter-hole pattern and the second supporter-hole pattern are offset in the second direction.

According to some embodiments of the present disclosure, a method of manufacturing a semiconductor memory device includes forming a first mold layer and a first supporter pattern on the first mold layer, forming a plurality of first through-holes penetrating the first mold layer and the first supporter pattern in a first direction, forming first portions of a plurality of lower electrodes in the plurality of first through-holes, removing part of the first supporter pattern such that a part of the first portions of the plurality of lower electrodes is exposed, forming a liner film on the first portions of the plurality of lower electrodes and on a remaining part of the first supporter pattern, removing part of the liner film to form openings exposing part of the first supporter pattern, and removing the part of the first supporter pattern exposed through the openings to form first supporter holes.

In some embodiments of the present disclosure, the method may further include forming a liner film on the first portions of the plurality of lower electrodes and on the remaining part of the first supporter pattern, the forming of the liner film may be performed by atomic layer deposition.

In some embodiments of the present disclosure, forming the openings may be performed by an etch-back process on the liner film.

In some embodiments of the present disclosure, the method may further include removing the first mold layer through the first supporter holes after forming the first supporter holes.

In some embodiments of the present disclosure, the method may further include forming a sacrificial layer on side surfaces of the first portions of the plurality of lower electrodes through the first supporter holes, forming a second mold layer on the first supporter pattern and a second supporter pattern on the second mold layer, forming a plurality of second through-holes by removing parts of the second mold layer and the second supporter pattern, and forming second portions of the plurality of lower electrodes in the plurality of second through-holes.

In some embodiments of the present disclosure, the method may further include removing part of the second supporter pattern to form second supporter holes.

In some embodiments of the present disclosure, the second portions of the plurality of lower electrodes may overlap at least parts of the first portions of the plurality of lower electrodes in the first direction and may be located at different positions in a second direction perpendicular to the first direction.

In some embodiments of the present disclosure, the second supporter holes may be located at positions different from the first supporter holes in the second direction.

In some embodiments of the present disclosure, the method may further include removing the second mold layer and the sacrificial layer through the second supporter holes, forming a dielectric layer on the plurality of lower electrodes, the first supporter pattern, and the second supporter pattern, and forming an upper electrode on the dielectric layer.

According to some embodiments of the present disclosure, first supporter holes are formed in the first supporter pattern before forming the second portions of the plurality of lower electrodes, thereby reducing process difficulty.

According to some embodiments of the present disclosure, because the supporter pattern can be patterned without using a separate photoresist and/or mask layer, process cost can be reduced.

### BRIEF DESCRIPTION OF THE DRAWINGS

FIG. 1 illustrates a layout of a semiconductor memory device according to some embodiments of the present disclosure.

FIGS. 2 and 3 are enlarged views illustrating a part of the semiconductor memory device of FIG. 1.

FIG. 4 is a cross-sectional view illustrating the semiconductor memory device taken along line A–A′ of FIG. 2 or FIG. 3.

FIG. 5 is a cross-sectional view illustrating the semiconductor memory device taken along line B–B′ of FIG. 2 or FIG. 3.

FIGS. 6-10 are cross-sectional views illustrating a part of a semiconductor memory device taken along line A–A′ or B–B′ of FIG. 2 or FIG. 3 according to some embodiments of the present disclosure.

FIG. 11 illustrates a layout of a semiconductor memory device according to some embodiments of the present disclosure.

FIGS. 12 and 13 are enlarged views illustrating a part of the semiconductor memory device of FIG. 11.

FIG. 14 is a cross-sectional view illustrating the semiconductor memory device taken along line C–C′ of FIG. 12 or FIG. 13.

FIGS. 15-21 are cross-sectional views taken along a line corresponding to A–A′ or B–B′ of FIG. 2 or FIG. 3 for explaining a method of manufacturing a semiconductor memory device according to some embodiments of the present disclosure.

FIGS. 22-26 are cross-sectional views taken along a line corresponding to B–B′ of FIG. 2 or FIG. 3 for explaining a method of manufacturing a semiconductor memory device according to some embodiments of the present disclosure.

FIGS. 27-29 are cross-sectional views taken along a line corresponding to B–B′ of FIG. 2 or FIG. 3 for explaining a method of manufacturing a semiconductor memory device according to some embodiments of the present disclosure.

### DETAILED DESCRIPTION

Hereinafter, semiconductor memory devices according to some embodiments of the present disclosure will be described in detail with reference to the drawings.

Throughout the specification, when a component is described as "including" a particular element or group of elements, it is to be understood that the component is formed of only the element or the group of elements, or the element or group of elements may be combined with additional elements to form the component, unless the context clearly and/or explicitly describes the contrary.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

It will be understood that when an element is referred to as being "connected" or "coupled" to or “on” another element, it can be directly connected or coupled to or on the other element or intervening elements may be present. In contrast, when an element is referred to as being "directly connected" or "directly coupled" to another element, or as “contacting” or “in contact with” another element (or using any form of the word “contact”), there are no intervening elements present at the point of contact.

As used herein, components described as being “electrically connected” are configured such that an electrical signal can be transferred from one component to the other (although such electrical signal may be attenuated in strength as it is transferred and may be selectively transferred).

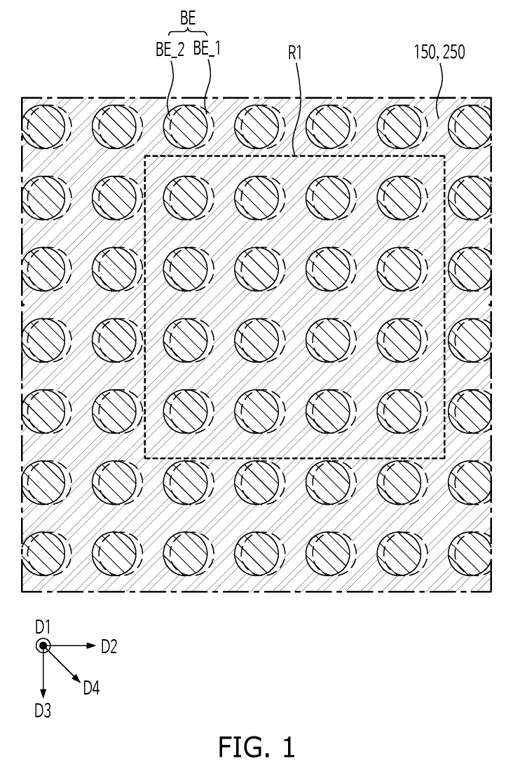

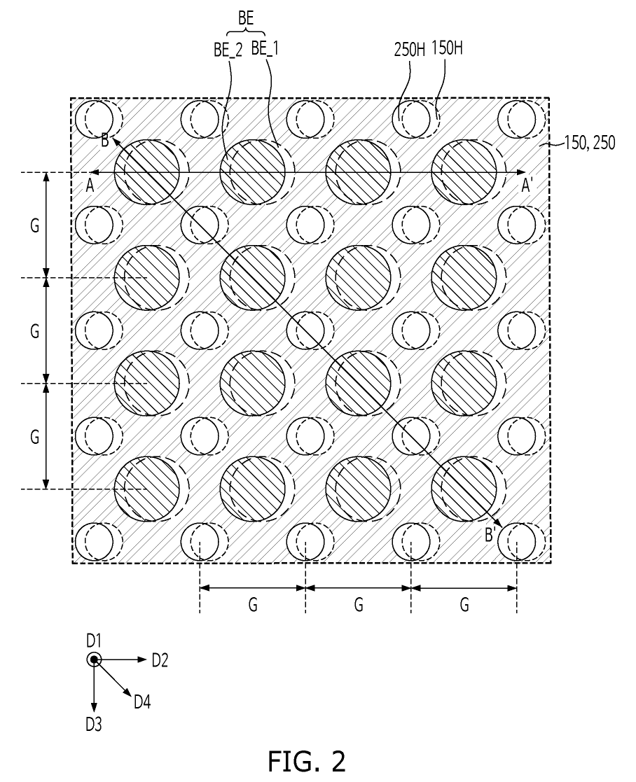

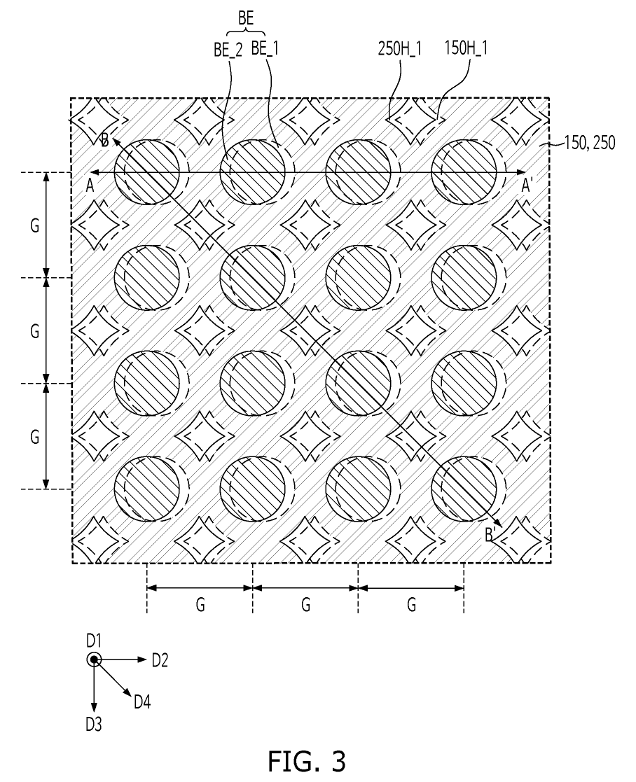

FIG. 1 illustrates a layout of a semiconductor memory device according to some embodiments of the present disclosure. FIGS. 2 and 3 are enlarged views illustrating a part of the semiconductor memory device of FIG. 1. FIGS. 2 and 3 may be region R1 of FIG. 1. For convenience, in FIGS. 1-3, components other than the second supporter pattern 250, the lower electrodes BE, the first supporter holes 150H, and the second supporter holes 250H are omitted.

Referring to FIGS. 1 and 2, the semiconductor memory device according to some embodiments of the present disclosure may include a plurality of lower electrodes BE and supporter patterns 150 and 250.

Each of the plurality of lower electrodes BE may include a first portion BE_1 and a second portion BE_2. The second portion BE_2 may be disposed on the first portion BE_1. The second portion BE_2 may overlap a part of the first portion BE_1 in a first direction D1 (e.g., a vertical direction). In some embodiments, an area of the second portion BE_2 may be larger than an area of the first portion BE_1, e.g., in a plan view, such that the second portion BE_2 may overlap all of the first portion BE_1 in the first direction D1.

The first portion BE_1 and the second portion BE_2 may be located at different positions in a second direction D2. For example, a center of the second portion BE_2 may not vertically overlap a center of the corresponding first portion BE_1 in a plan view. For example, the second portion BE_2 may be offset from the first portion BE_1 in the second direction D2. This is merely an example, and offsetting may occur in another direction perpendicular to the first direction D1. In the present embodiment, each of the plurality of second portions BE_2 is illustrated as being offset in the same direction, e.g., in the second direction D2, with respect to a corresponding one of the plurality of first portions BE_1, but the present disclosure is not limited thereto. Each of the plurality of second portions BE_2 may be offset in different directions from others with respect to the plurality of first portions BE_1. For example, the second portion BE_2 may be shifted from the first portion BE_1 in a plan view.

The plurality of lower electrodes BE may extend lengthwise along the first direction D1. For example, each of the first portion BE_1 and the second portion BE_2 may extend lengthwise in the first direction D1. The plurality of lower electrodes BE may be arranged along the second direction D2 and a third direction D3. For example, the second and third directions D2 and D3 may be horizontal directions.

The lower electrodes BE may be arranged to have a grid pattern. For example, the lower electrodes BE may be arranged in a matrix pattern, e.g., in a plan view, and the supporter patterns 150 and 250 may be formed in a grid pattern, e.g., in the plan view. For example, the lower electrodes BE may be arranged spaced apart in the second direction D2 and the third direction D3. The lower electrodes BE may be arranged at a first pitch G along the second direction D2 and the third direction D3. For example, first portions BE_1 and second portions BE_2 of the lower electrodes BE may be arranged spaced apart by the first pitch G in the second direction D2 and the third direction D3. For example, four lower electrodes BE may be disposed at corners of a square, and squares in which the lower electrodes BE are disposed at corners may be repeated in the second direction D2 and the third direction D3. For example, the squares on which corners the lower electrodes BE are positioned may be imaginary squares. The lower electrodes BE may be linearly arranged along a fourth direction D4. Here, the second direction D2 and the third direction D3 may each be perpendicular to the first direction D1. The fourth direction D4 may intersect the second direction D2 and the third direction D3. For example, the fourth direction D4 may form a predetermined angle, e.g., 45 degrees, with each of the second direction D2 and the third direction D3. The fourth direction D4 may be a horizontal direction and be perpendicular to the first direction D1 (e.g., the vertical direction).

The first supporter pattern 150 and the second supporter pattern 250 may support the lower electrodes BE. The first supporter pattern 150 and the second supporter pattern 250 may surround sidewalls of the lower electrodes BE. For example, the first supporter pattern 150 may surround a sidewall of the first portion BE_1 of the lower electrodes BE, and the second supporter pattern 250 may surround a sidewall of the second portion BE_2 of the lower electrodes BE. The first supporter pattern 150 and the second supporter pattern 250 may each be disposed perpendicular to the first direction D1. For example, the first supporter pattern 150 and the second supporter pattern 250 may extend in a direction perpendicular to the first direction D1. The first supporter pattern 150 and the second supporter pattern 250 may be spaced apart in the first direction D1. For example, the second supporter pattern 250 may be spaced upward from the first supporter pattern 150.

Each of the first supporter pattern 150 and the second supporter pattern 250 may include a plurality of first supporter holes 150H and a plurality of second supporter holes 250H, respectively.

The first supporter holes 150H may be spaced apart from each other at a predetermined distance. The second supporter holes 250H may be spaced apart from each other at a predetermined distance. The first supporter holes 150H and the second supporter holes 250H may each be arranged to have a grid pattern. For example, the first and second supporter holes 150H and 250H may be arranged in a matrix form such that the first and second patterns 150 and 250 form grid patterns, e.g., in a plan view. The first supporter holes 150H and the second supporter holes 250H may each be arranged spaced apart in the second direction D2 and the third direction D3. For example, the first supporter holes 150H and the second supporter holes 250H may each be arranged at the first pitch G along the second direction D2 and the third direction D3. For example, the first supporter holes 150H and the second supporter holes 250H may be arranged spaced apart by the first pitch G in the second direction D2 and the third direction D3. For example, the first supporter holes 150H and the second supporter holes 250H may have the same pitch in the second direction D2 and in the third direction D3.

Each of the first supporter holes 150H and the second supporter holes 250H may have a rounded closed-curve shape. For example, each of the first supporter holes 150H and the second supporter holes 250H may have a circular or elliptical shape, e.g., in a plan view. For example, each of the first supporter holes 150H and the second supporter holes 250H may have a circular cylinder shape or an elliptic cylinder shape.

Each first supporter hole 150H may be located among/between first portions BE_1 of a plurality of lower electrodes BE adjacent to the first supporter hole 150H. A plurality of first portions BE_1 adjacent to the first supporter hole 150H may be located at corners of a square, and the first supporter hole 150H may be located inside the square. In some embodiments, the plurality of first portions BE_1 adjacent to the first supporter hole 150H may be located at corners of a square, and the first supporter hole 150H may be located at a center of the square. For example, connecting adjacent four first portions BE_1 with lines may form a square and a first supporter hole 150H may be located at a center of the square, e.g., in a plan view. For example, a distance between a center of the first supporter hole 150H and a center of each of the plurality of first portions BE_1 (e.g., four first portions BE_1) adjacent to the first supporter hole 150H may be identical.

Each second supporter hole 250H may be located among/between second portions BE_2 of a plurality of lower electrodes BE adjacent to the second supporter hole 250H. A plurality of second portions BE_2 adjacent to the second supporter hole 250H may be located at corners of a square, and the second supporter hole 250H may be located inside the square. In some embodiments, the plurality of second portions BE_2 adjacent to the second supporter hole 250H may be located at corners of a square, and the second supporter hole 250H may be located at a center of the square. For example, connecting adjacent four second portions BE_2 with lines may form a square and a second supporter hole 250H may be located at a center of the square, e.g., in a plan view. For example, a distance between a center of the second supporter hole 250H and a center of each of the plurality of second portions BE_2 (e.g., four second portions BE_2) adjacent to the second supporter hole 250H may be identical.

The second portions BE_2 of the plurality of lower electrodes BE may be offset/shifted from the first portions BE_1 of the plurality of lower electrodes BE in the second direction D2, and the first supporter holes 150H and the second supporter holes 250H may be offset/shifted in the second direction D2. Furthermore, a grid pattern formed by the first portions BE_1 and the second portions BE_2 of the plurality of lower electrodes BE, respectively, and a grid pattern formed by the first supporter holes 150H and the second supporter holes 250H, respectively, may have an identical spacing.

As described above, a square structure in which a set of four first supporter holes 150H and a set of four second supporter holes 250H are disposed at respective corners of a square are repeated in the second direction D2 and the third direction D3. The first supporter holes 150H and the second supporter holes 250H may be linearly arranged along the fourth direction D4. For example, the first portions BE_1 and the first supporter holes 150H may be alternately arranged along the fourth direction D4, and the second portions BE_2 and the second supporter holes 250H may be alternately arranged along the fourth direction D4. For example, the fourth direction D4 may form an angle of 45 degrees with each of the second direction D2 and the third direction D3.

Referring to FIG. 3, the first supporter hole 150H_1 and the second supporter hole 250H_1 may have shapes different from the first supporter hole 150H and the second supporter hole 250H of FIG. 2. The first supporter hole 150H_1 and the second supporter hole 250H_1 may have a closed-curve shape including apexes/vertices. For example, the first supporter hole 150H_1 and the second supporter hole 250H_1 may have a closed-curve shape, e.g., in a plan view, in which four quadrants are symmetrically formed. For example, the closed-curve shape of each of the first supporter hole 150H_1 and the second supporter holes 250H_1 in the plan view may be formed by four quadrants/arcs of a circle arranged such that each of the four quadrants/arcs is convex toward a center of the first supporter hole 150H_1 or the second supporter hole 250H_1 and each quadrant/arc contacts adjacent quadrants/arcs at both ends so that the four quadrants/arcs together form a closed curve. In some embodiments, the first supporter hole 150H_1 and the second supporter hole 250H_1 may have a rhombus or diamond shape, e.g., in a plan view.

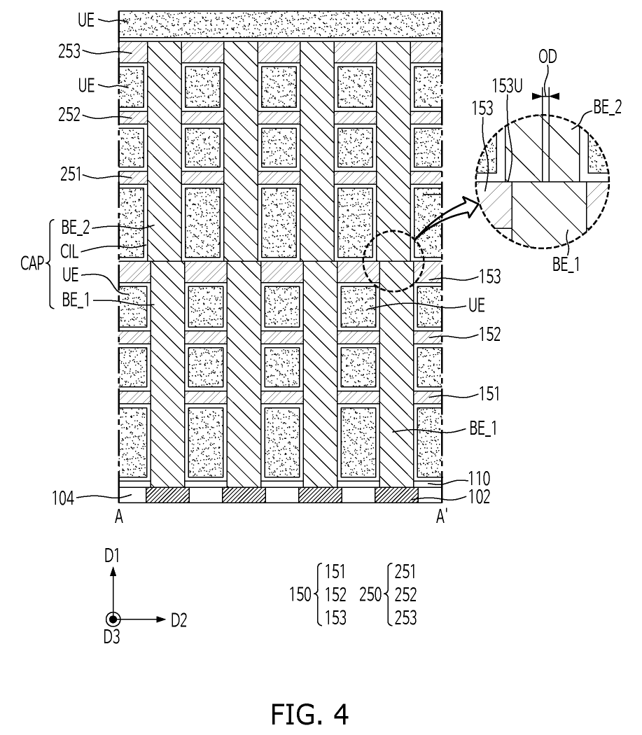

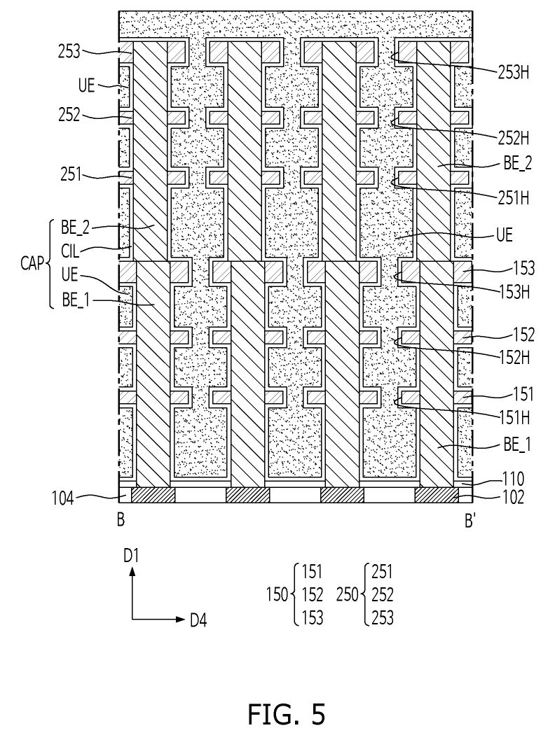

FIG. 4 is a cross-sectional view illustrating the semiconductor memory device taken along line A–A′ of FIG. 2 or FIG. 3. FIG. 5 is a cross-sectional view illustrating the semiconductor memory device taken along line B–B′ of FIG. 2 or FIG. 3.

Referring to FIGS. 4 and 5, the semiconductor memory device according to some embodiments of the present disclosure may include a plurality of conductive patterns 102, an isolation layer 104, a capacitor structure CAP, a first supporter pattern 150, and a second supporter pattern 250.

The plurality of conductive patterns 102 may be embedded in the isolation layer 104. An upper surface of each of the plurality of conductive patterns 102 may be located at the same vertical level as an upper surface of the isolation layer 104. In some embodiments, the upper surface of each of the plurality of conductive patterns 102 may be located at a lower vertical level than the upper surface of the isolation layer 104. The plurality of conductive patterns 102 may be electrically connected to the lower electrodes BE. The isolation layer 104 may electrically isolate the plurality of conductive patterns 102 from each other. The plurality of conductive patterns 102 may include a conductive material. The isolation layer 104 may include an insulating material such as silicon oxide.

An etch-stop layer 110 may be disposed on the isolation layer 104. For example, the etch-stop layer 110 may include silicon nitride, silicon oxynitride, or a combination thereof. The etch-stop layer 110 may prevent an etchant from entering beneath the lower electrodes BE during a wet etching process, thereby preventing the isolation layer 104 from being etched.

The capacitor structure CAP may include the plurality of lower electrodes BE, a dielectric layer CIL, and an upper electrode UE.

The plurality of lower electrodes BE may be disposed on the plurality of conductive patterns 102. Specifically, the first portions BE_1 of the plurality of lower electrodes BE may be disposed on the plurality of conductive patterns 102. The second portions BE_2 of the plurality of lower electrodes BE may be stacked on the first portions BE_1. The first portions BE_1 and the second portions BE_2 may be located at different positions in the second direction D2. For example, the second portions BE_2 may be offset from the first portions BE_1 in the second direction D2. A center line of the second portions BE_2 may be located at a position spaced apart from a center line of the first portions BE_1 by an offset distance OD in the second direction D2. Here, the center lines of the first portions BE_1 and the second portions BE_2 may extend in the first direction D1. For example, side surfaces of the second portions BE_2 may have a step difference from side surfaces of the first portions BE_1.

The plurality of lower electrodes BE may have a pillar shape. For example, each of the first portion BE_1 and the second portion BE_2 may have a pillar shape extending lengthwise along the first direction D1. However, the present disclosure is not limited thereto, and each of the plurality of lower electrodes BE may have a cross-sectional structure of a cup shape or a closed-bottom cylinder-shape.

The plurality of lower electrodes BE may be electrically connected to the conductive patterns 102. The plurality of lower electrodes BE may include a metal such as Ti, W, Ni, or Co, or a metal nitride such as TiN, TiSiN, TiAlN, TaN, TaSiN, or WN. In an embodiment, the lower electrodes BE may include TiN.

The dielectric layer CIL may be disposed between the plurality of lower electrodes BE and the upper electrode UE. The dielectric layer CIL may conformally cover the first portions BE_1 and the second portions BE_2 of the plurality of lower electrodes BE and the first supporter pattern 150 and the second supporter pattern 250. For example, the dielectric layer CIL may be conformally disposed on the etch-stop layer 110, the first portions BE_1 and the second portions BE_2 of the plurality of lower electrodes BE, the first supporter pattern 150, and the second supporter pattern 250. The dielectric layer CIL may include a metal oxide such as HfO₂, ZrO₂, Al₂O₃, La₂O₃, Ta₂O₃, or TiO₂, a dielectric material having a perovskite structure such as SrTiO₃ (STO), BaTiO₃, PZT, or PLZT, or a combination thereof.

The upper electrode UE may be disposed on the dielectric layer CIL. The upper electrode UE may cover the dielectric layer CIL. The upper electrode UE may include a metal such as Ti, W, Ni, or Co, or a metal nitride such as TiN, TiSiN, TiAlN, TaN, TaSiN, or WN.

The first supporter pattern 150 and the second supporter pattern 250 may be disposed inside the capacitor structure CAP. For example, the first supporter pattern 150 and the second supporter pattern 250 may be disposed among/between the plurality of lower electrodes BE and the dielectric layer CIL. The first supporter pattern 150 and the second supporter pattern 250 may be disposed among adjacent ones of the plurality of lower electrodes BE. For example, the first supporter pattern 150 and the second supporter pattern 250 may be disposed between adjacent ones of the plurality of lower electrodes BE. The first supporter pattern 150 and the second supporter pattern 250 may connect/contact the adjacent lower electrodes BE, and may support the lower electrodes BE, e.g., sidewalls of the lower electrodes BE.

The first supporter pattern 150 may surround side surfaces of the first portions BE_1 of the plurality of lower electrodes BE. A topmost portion of the first supporter pattern 150 may be located at the same vertical level as a topmost portion of the first portions BE_1 of the plurality of lower electrodes BE. The second supporter pattern 250 may surround side surfaces of the second portions BE_2 of the plurality of lower electrodes BE. An upper surface of the second supporter pattern 250 may be located at the same vertical level as a topmost portion of the second portions BE_2 of the plurality of lower electrodes BE. In some embodiments, when the first supporter pattern 150 is a single layer, an upper surface of the first supporter pattern 150 may be located at the same vertical level as an upper surface of the first portions BE_1 of the plurality of lower electrodes BE.

The first supporter pattern 150 may include a plurality of first supporter layers 151, 152, and 153 in which a first supporter-hole pattern including first supporter holes 151H, 152H, and 153H is formed. The second supporter pattern 250 may include a plurality of second supporter layers 251, 252, and 253 in which a second supporter-hole pattern including second supporter holes 251H, 252H, and 253H is formed. In the present disclosure, the first supporter pattern 150 and the second supporter pattern 250 are illustrated as each including three layers, but the present disclosure is not limited thereto. In some embodiments, the first supporter pattern 150 and the second supporter pattern 250 may each include a different number of layers. Hereinafter, the first supporter pattern 150 and the second supporter pattern 250 will be described as each including three layers.

The plurality of first supporter layers 151, 152, and 153 may include a first-1 supporter layer 151, a first-2 supporter layer 152, and a first-3 supporter layer 153. The first-1 supporter layer 151, the first-2 supporter layer 152, and the first-3 supporter layer 153 may be located at different vertical levels. The first-1 supporter layer 151, the first-2 supporter layer 152, and the first-3 supporter layer 153 may be spaced apart from each other in the first direction D1. The first-1 supporter layer 151 may be spaced apart from the etch-stop layer 110 in the first direction D1. The first-2 supporter layer 152 may be disposed above the first-1 supporter layer 151, and the first-3 supporter layer 153 may be disposed above the first-2 supporter layer 152. The dielectric layer CIL and the upper electrode UE may be disposed between the supporter layers 151, 152, and 153. An upper surface of the first-3 supporter layer 153 may be located at the same vertical level as an upper surface of the first portions BE_1 of the plurality of lower electrodes BE. The upper surface of the first-3 supporter layer 153 may be coplanar with the upper surface of the first portions BE_1 of the plurality of lower electrodes BE.

A topmost surface of the first supporter pattern 150 may contact a bottommost surface of the second portions BE_2 of the plurality of lower electrodes BE. An upper surface 153U of the first-3 supporter layer 153 is located at the same vertical level as an upper surface of the first portions BE_1 of the plurality of lower electrodes BE, and the second portions BE_2 of the plurality of lower electrodes BE are offset from the first portions BE_1 in the second direction D2. Therefore, the upper surface 153U of the first-3 supporter layer 153 may contact a bottommost surface of the second portions BE_2 of the plurality of lower electrodes BE.

The first-1 supporter layer 151, the first-2 supporter layer 152, and the first-3 supporter layer 153 may include first supporter holes 151H, 152H, and 153H, respectively. The first supporter holes 151H, 152H, and 153H may be formed in the first-1 supporter layer 151, the first-2 supporter layer 152, and the first-3 supporter layer 153, respectively. Accordingly, the first supporter holes 151H, 152H, and 153H may be spaced apart from each other in the first direction D1. The first supporter holes 151H, 152H, and 153H may be aligned in the first direction D1. For example, the first supporter-hole pattern includes the first supporter holes 151H, 152H, and 153H aligned and spaced apart from each other in the first direction D1.

Thicknesses of the first-1 supporter layer 151, the first-2 supporter layer 152, and the first-3 supporter layer 153 may differ. Here, each thickness of the first-1 supporter layer 151, the first-2 supporter layer 152, and the first-3 supporter layer 153 may be defined as a thickness in the first direction D1. For example, a thickness of the first-3 supporter layer 153 may be greater than the thickness of the first-1 supporter layer 151 and the thickness of the first-2 supporter layer 152. However, this is merely exemplary, and the thicknesses of the first-1 supporter layer 151, the first-2 supporter layer 152, and the first-3 supporter layer 153 may vary.

The second supporter pattern 250 may include a second-1 supporter layer 251, a second-2 supporter layer 252, and a second-3 supporter layer 253. The second-1 supporter layer 251, the second-2 supporter layer 252, and the second-3 supporter layer 253 may be located at different vertical levels. The second-1 supporter layer 251, the second-2 supporter layer 252, and the second-3 supporter layer 253 may be spaced apart from each other in the first direction D1. The second-1 supporter layer 251 may be spaced from the etch-stop layer 110 in the first direction D1. The second-2 supporter layer 252 may be disposed above the second-1 supporter layer 251, and the second-3 supporter layer 253 may be disposed above the second-2 supporter layer 252. The dielectric layer CIL and the upper electrode UE may be disposed between the second-1 supporter layer 251, the second-2 supporter layer 252, and the second-3 supporter layer 253. For example, the dielectric layer CIL and the upper electrode UE may vertically overlap the second-1 supporter layer 251 and the second-2 supporter layer 252 between the second-1 supporter layer 251 and the second-2 supporter layer 252, and the dielectric layer CIL and the upper electrode UE may vertically overlap the second-2 supporter layer 252 and the second-3 supporter layer 253 between the second-2 supporter layer 252 and the second-3 supporter layer 253. An upper surface of the second-3 supporter layer 253 may be located at the same vertical level as an upper surface of the second portions BE_2 of the plurality of lower electrodes BE. The upper surface of the second-3 supporter layer 253 may be coplanar with the upper surface of the second portions BE_2 of the plurality of lower electrodes BE.

The second-1 supporter layer 251, the second-2 supporter layer 252, and the second-3 supporter layer 253 may include second supporter holes 251H, 252H, and 253H, respectively. The second supporter holes 251H, 252H, and 253H may be formed in the second-1 supporter layer 251, the second-2 supporter layer 252, and the second-3 supporter layer 253, respectively. Accordingly, the second supporter holes 251H, 252H, and 253H may be spaced apart in the first direction D1. The second supporter holes 251H, 252H, and 253H may be aligned in the first direction D1. For example, the second supporter-hole pattern includes the second supporter holes 251H, 252H, and 253H aligned (e.g., overlap each other) and spaced in the first direction D1.

The first supporter-hole pattern including the first supporter holes 151H, 152H, and 153H and the second supporter-hole pattern including the second supporter holes 251H, 252H, and 253H may be offset in the second direction D2. The first supporter holes 151H, 152H, and 153H may be located at an identical distance (e.g. a distance DA) from adjacent first portions BE_1 of the plurality of lower electrodes BE, and the second supporter holes 251H, 252H, and 253H may be located at an identical distance (e.g., a distance DB) from adjacent second portions BE_2 of the plurality of lower electrodes BE. For example, the distance DA and the distance DB may be the same.

Thicknesses of the second-1 supporter layer 251, the second-2 supporter layer 252, and the second-3 supporter layer 253 may differ. Here, each thickness of the second-1 supporter layer 251, the second-2 supporter layer 252, and the second-3 supporter layer 253 may be defined as a thickness in the first direction D1. For example, a thickness of the second-3 supporter layer 253 may be greater than the thickness of the second-1 supporter layer 251 and the thickness of the second-2 supporter layer 252. However, this is merely exemplary, and the thicknesses of the second-1 supporter layer 251, the second-2 supporter layer 252, and the second-3 supporter layer 253 may vary.

Each of the first supporter pattern 150 and the second supporter pattern 250 may include at least one of silicon oxynitride (SiON), silicon nitride (SiN), silicon carbon nitride (SiCN), or tantalum oxide (TaO). In some embodiments, the first supporter pattern 150 and the second supporter pattern 250 may include identical materials, but the present disclosure is not limited thereto. For example, the first supporter pattern 150 and the second supporter pattern 250 may include different materials.

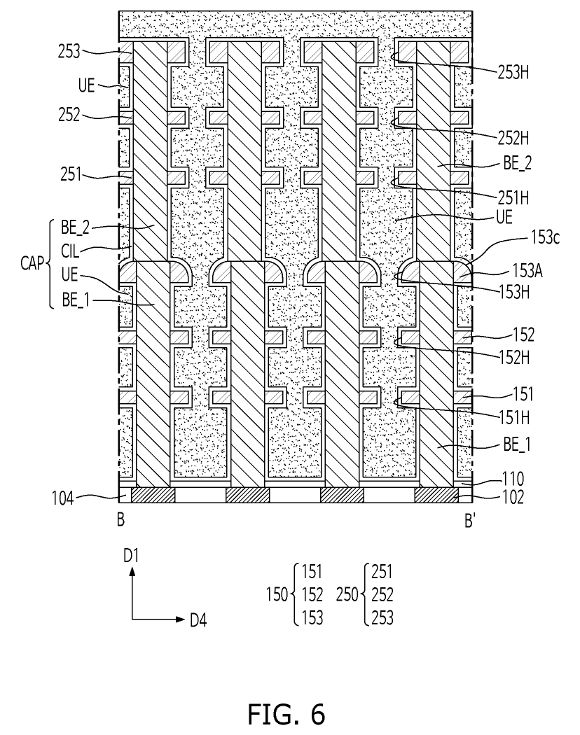

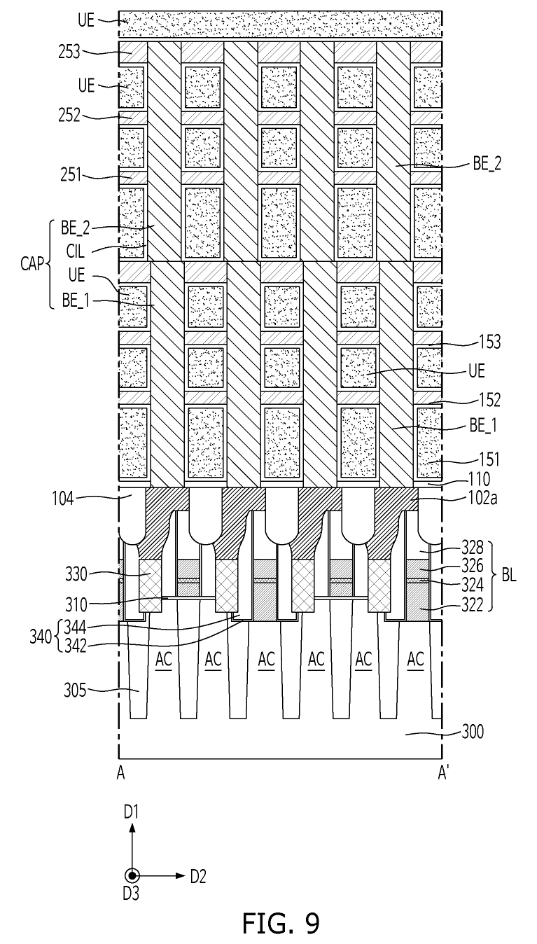

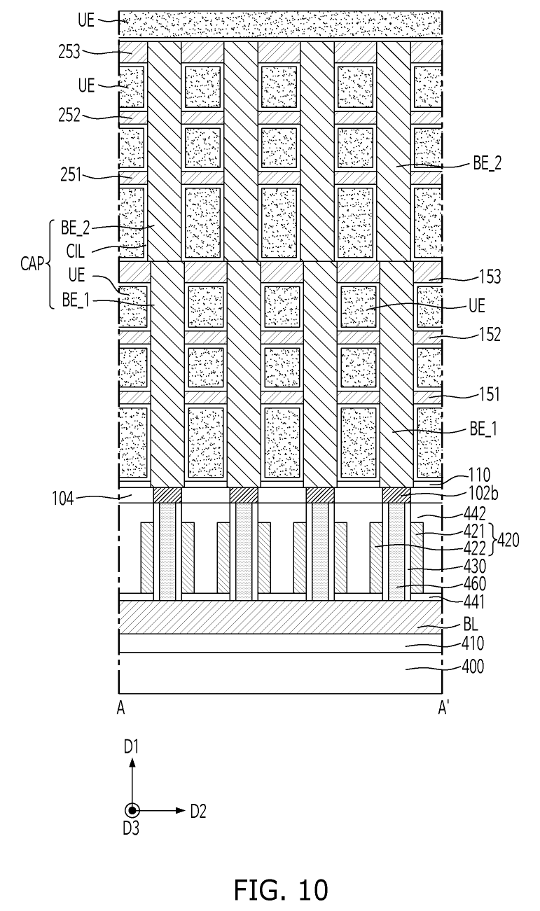

FIGS. 6-10 are cross-sectional views illustrating a part of a semiconductor memory device according to some embodiments of the present disclosure. For convenience, parts different from those described with reference to FIGS. 1-5 will be explained. For example, the parts described with respect to FIGS. 1-5 may also be applied to the embodiments illustrated in FIGS. 6-10 unless context indicates otherwise. FIGS. 6-8 may correspond to or may be a cross-section taken along line B–B′ of FIG. 2 or FIG. 3, and FIGS. 9-10 may correspond to or may be a cross-section taken along line A–A′ of FIG. 2 or FIG. 3.

Referring to FIG. 6, in a semiconductor memory device according to some embodiments of the present disclosure, the first supporter pattern 150 may include a first curved portion 153c.

The first curved portion 153c may define an upper surface and a side surface of the first supporter pattern 150. The first curved portion 153c may have a rounded shape. For example, the first curved portion 153c may define an upper surface and a side surface of the first-3 supporter layer 153A. The first curved portion 153c may be convex toward the second supporter pattern 250. The first curved portion 153c may be convex upward. For example, the first-3 supporter layer 153 may have a fan shape cross-section or a sector shape cross-section.

A side surface of the supporter layer 153A may be rounded. A side surface of the first-3 supporter layer 153A may be curved. The first-3 supporter layer 153A may have a width, e.g., in a horizontal direction, that increases in a direction moving downward. A width, e.g., in the horizontal direction, at a lower end of the first-3 supporter layer 153A may be greater than a width, e.g., in the horizontal direction, at an upper end of the first-3 supporter layer 153A. A width, e.g., in the horizontal direction, of the first supporter hole 153H formed in the first-3 supporter layer 153A may decrease in a direction moving downward. An upper end of the first-3 supporter layer 153A may be located at the same vertical level as a topmost portion of the first portions BE_1 of the plurality of lower electrodes BE.

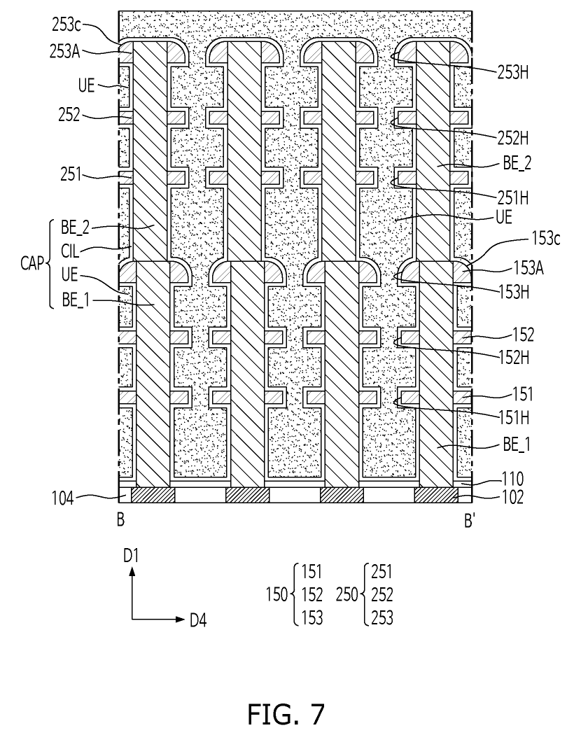

Referring to FIG. 7, in a semiconductor memory device according to some embodiments of the present disclosure, the second supporter pattern 250 may include a second curved portion 253c.

The second curved portion 253c may define an upper surface and a side surface of the second supporter pattern 250. The second curved portion 253c may have a rounded shape. For example, the second curved portion 253c may define an upper surface and a side surface of the second-3 supporter layer 253A. The second curved portion 253c may be convex in a direction away from the first supporter pattern 150, e.g., convex upwards. The second curved portion 253c may be convex in the same direction as the first curved portion 153c. The second curved portion 253c may be convex upward. For example, the second-3 supporter layer 253 may have a fan shape cross-section or a sector shape cross-section.

A side surface of the supporter layer 253A may be rounded. A side surface of the second-3 supporter layer 253A may be curved. The second-3 supporter layer 253A may have a width, e.g., in a horizontal direction, that increases in a direction moving downward. A width, e.g., in the horizontal direction, at a lower end of the second-3 supporter layer 253A may be greater than a width, e.g., in the horizontal direction, at an upper end of the second-3 supporter layer 253A. A width, e.g., in the horizontal direction, of the second supporter hole 253H formed in the second-3 supporter layer 253A may decrease in the direction moving downward. An upper end of the second-3 supporter layer 253A may be located at the same vertical level as a topmost portion of the second portions BE_2 of the plurality of lower electrodes BE.

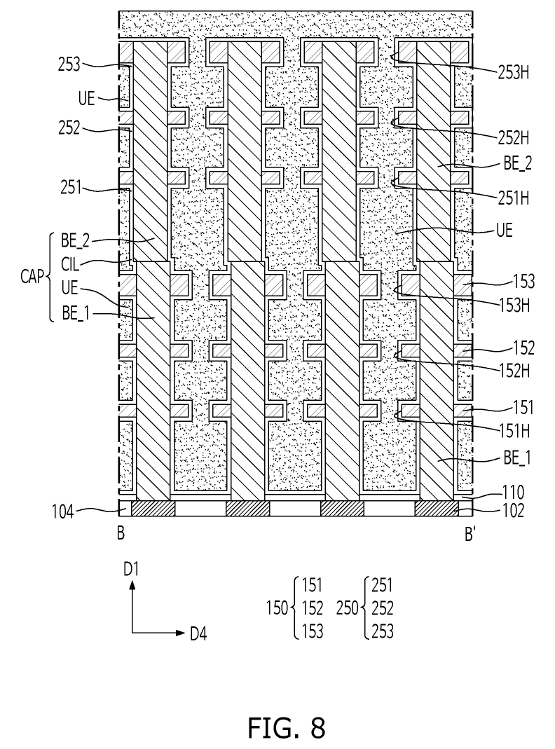

Referring to FIG. 8, a topmost portion of the first portions BE_1 of the plurality of lower electrodes BE may be located at a higher vertical level than a topmost portion of the first supporter pattern 150. For example, the first portions BE_1 of the plurality of lower electrodes BE may protrude upward from the topmost portion of the first supporter pattern 150. An upper surface of the first supporter pattern 150 may be spaced in the first direction D1 from the second portions BE_2 of the plurality of lower electrodes BE. For example, the upper surface of the first supporter pattern 150 may not contact a bottommost surface of the second portions BE_2 of the plurality of lower electrodes BE.

For example, an upper surface of the first-3 supporter layer 153 may be located at a lower vertical level than a topmost portion of the first portions BE_1 of the plurality of lower electrodes BE. An upper surface of the first-3 supporter layer 153 may be spaced in the first direction D1 from the second portions BE_2 of the plurality of lower electrodes BE. The upper surface of the first-3 supporter layer 153 may not contact a bottommost surface of the second portions BE_2 of the plurality of lower electrodes BE. In some embodiments, a topmost portion of the second portions BE_2 of the plurality of lower electrodes BE may be located at a higher vertical level than a topmost portion of the second supporter pattern 250.

Referring to FIG. 9, a semiconductor memory device according to some embodiments of the present disclosure may comprise a substrate 300, an interlayer insulating layer 310, a bit-line structure BL, a bit-line spacer 340, a buried contact 330, and an isolation layer 104. In an embodiment of the present disclosure, the conductive pattern 102 (see FIG. 4) may be a landing pad 102a.

The substrate 300 may include a plurality of active patterns AC. The active patterns AC may be defined by a device isolation layer 305 formed in the substrate 300. The active patterns AC may have a bar shape. The plurality of active patterns AC may be arranged spaced apart from each other. The device isolation layer 305 may have a shallow trench isolation (STI) structure. Each device isolation layer 305 may include, for example, at least one of a silicon oxide film, a silicon nitride film, or a silicon oxynitride film, although the present disclosure is not limited thereto. Each device isolation layer 305 is illustrated as being formed of a single insulating film for convenience of description, but the present disclosure is not limited thereto.

The interlayer insulating layer 310 may be disposed on an upper surface of the substrate 300. In an embodiment, the interlayer insulating layer 310 may include silicon oxide, silicon nitride, silicon oxynitride, or a combination thereof.

The bit-line structure BL may be disposed on the substrate 300. For example, the bit-line structure BL may be disposed on an upper surface of the interlayer insulating layer 310 or may be disposed penetrating a part of an upper portion of the substrate 300. The bit-line structure BL may include a bit-line contact 322, a bit-line barrier layer 324, a bit-line 326, and a bit-line capping layer 328 stacked in sequence.

The bit-line contact 322 may contact an active pattern AC (for example, a source region). The bit-line 326 may be electrically connected to the active pattern AC through the bit-line contact 322 and the bit-line barrier layer 324. The bit-line contact 322 may include, for example, at least one of an impurity-doped semiconductor material, a conductive silicide compound, a conductive metal nitride, and/or a metal.

The bit-line barrier layer 324 may include a barrier metal such as titanium nitride (TiN). The bit-line 326 may include a metal such as tungsten W. The bit-line capping layer 328 may include silicon nitride and/or silicon oxynitride.

The bit-line spacers 340 may be disposed on side surfaces of the bit-line structure BL. A bit-line spacer 340 formed on a bit-line structure BL in which the bit-line contact 322 is formed may be formed on the substrate 300 and the device isolation layer 305. A bit-line spacer 340 formed on a bit-line structure BL in which the bit-line contact 322 is not formed, the bit-line spacer 340 may be disposed on the interlayer insulating layer 310. The bit-line spacer 340 may be disposed on a sidewall of the bit-line structure BL.

The bit-line spacer 340 may be a single film. However, as illustrated in the figures, the bit-line spacer 340 may be formed of multilayer of films to have a multi-film structure including a first spacer 342 and a second spacer 344. For example, each of the first spacer 342 and the second spacer 344 may include one of silicon oxide, silicon nitride, silicon oxynitride (SiON), silicon oxy-carbon-nitride (SiOCN), air, or a combination thereof, although the present disclosure is not limited thereto.

The buried contact 330 may be disposed between bit-line structures BL adjacent to each other in the second direction D2. The buried contact 330 may penetrate a part of the substrate 300. The buried contact 330 may be electrically connected to the active pattern AC. The buried contact 330 may electrically connect the active pattern AC and the capacitor structure CAP. The buried contact 330 may include, for example, at least one of an impurity-doped semiconductor material, a conductive silicide compound, a conductive metal nitride, or a metal.

The landing pad 102a may be formed on the buried contact 330. The landing pad 102a may be electrically connected to the buried contact 330. The landing pad 102a may be disposed between the buried contact 330 and the lower electrode BE. By enlarging a contact area through the landing pad 102a, a contact resistance between the active pattern AC and the lower electrode BE may be reduced. The landing pad 102a may include, for example, at least one of an impurity-doped semiconductor material, a conductive silicide compound, a conductive metal nitride, a conductive metal carbide, a metal, or a metal alloy.

Referring to FIG. 10, a semiconductor memory device according to some embodiments of the present disclosure may further include a substrate 400, a lower insulating layer 410, a bit-line structure BL, an active pattern 460, a gate electrode 420, a gate insulating layer 430, and buried layers 441 and 442. The semiconductor memory device of the present disclosure may be a memory device including a vertical-channel transistor VCT. The vertical-channel transistor may be a structure in which a channel length of the active pattern 460 extends in a direction perpendicular to an upper surface of the substrate 400. In an embodiment of the present disclosure, the conductive pattern 102 (see FIG. 4) may be a capacitor contact 102b.

The lower insulating layer 410 and the bit-line structure BL may be sequentially disposed on the substrate 400. The bit-line structure BL may be disposed on the lower insulating layer 410. The bit-line structure BL may include a plurality of conductive lines extending in the second direction D2 and spaced in the third direction D3. The bit-line structure BL may include doped polysilicon, a metal, a conductive metal nitride, a conductive metal silicide, a conductive metal oxide, or a combination thereof.

The active patterns 460 may be arranged spaced apart from each other on the bit-line structure BL in the second direction D2 and the third direction D3. For example, a bottom portion of the active pattern 460 may serve as a first source/drain region, an upper portion of the active pattern 460 may serve as a second source/drain region, and a portion between the first source/drain region and the second source/drain region may serve as a channel region.

The gate electrode 420 may extend in the third direction D3 on side surfaces of the active pattern 460. The gate electrode 420 may include a first gate electrode 421 facing one side surface of the active pattern 460 and a second gate electrode 422 facing the other side surface of the active pattern 460. Because one active pattern 460 is disposed between the first gate electrode 421 and the second gate electrode 422, the semiconductor memory device may have a dual-gate transistor structure. However, the present disclosure is not limited thereto, and a single-gate transistor structure may also be implemented.

The gate electrode 420 may include doped polysilicon, a metal, a conductive metal nitride, a conductive metal silicide, a conductive metal oxide, or a combination thereof. For example, the gate electrode 420 may include doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof, but the present disclosure is not limited thereto.

The gate insulating layer 430 may be disposed on side surfaces of the active pattern 460. The gate insulating layer 430 may be interposed between the active pattern 460 and the gate electrode 420. For example, an entire sidewall of the active pattern 460 may be surrounded by the gate insulating layer 430, and part of a sidewall of the gate electrode 420 may contact the gate insulating layer 430. For example, the gate insulating layer 430 may include silicon oxide, silicon oxynitride, a high-k dielectric having a higher dielectric constant than silicon oxide, or a combination thereof. The high-k dielectric may include a metal oxide or a metal oxynitride. For example, a high-k dielectric usable as the gate insulating layer 430 may include HfO₂, HfSiO, HfSiON, HfTaO, HfTiO, HfZrO, ZrO₂, Al₂O₃, or a combination thereof, but the present disclosure is not limited thereto.

The buried layers 441 and 442 may be disposed between active patterns 460 adjacent to each other in the second direction D2. A first buried layer 441 may be disposed at a bottom of a space between two adjacent active patterns 460, and a second buried layer 442 may be formed on the first buried layer 441 to fill a remaining space between the two adjacent active patterns 460. An upper surface of the second buried layer 442 may be disposed at the same level as an upper surface of the active pattern 460, and the second buried layer 442 may cover/contact an upper surface of the gate electrode 420. The first buried layer 441 and the second buried layer 442 may be provided as a continuous material layer, e.g., as one body, in certain embodiment.

The capacitor contact 102b may be disposed on the active pattern 460. The capacitor contact 102b may be disposed overlapping the active pattern 460 in the first direction D1 and arranged spaced apart from other capacitor contacts 102b in the second direction D2 and the third direction D3. The capacitor contact 102b may include doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof, but the present disclosure is not limited thereto.

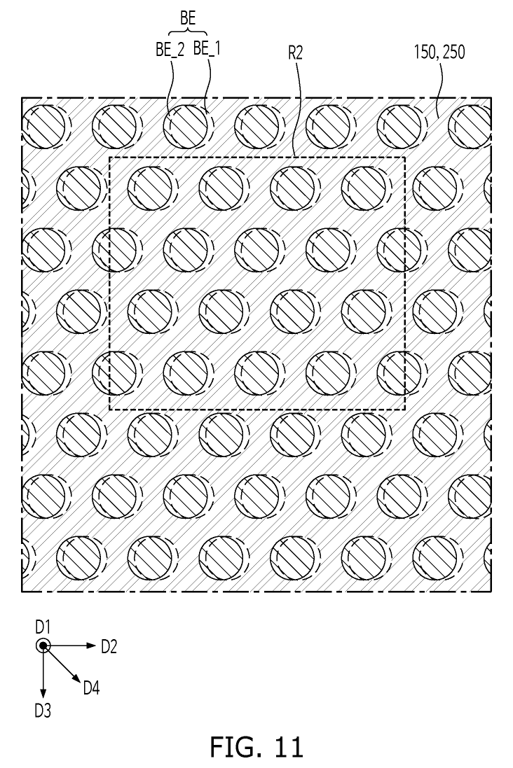

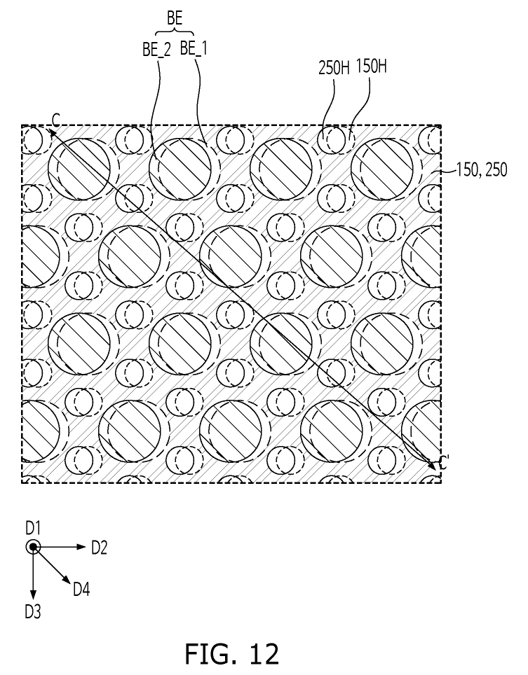

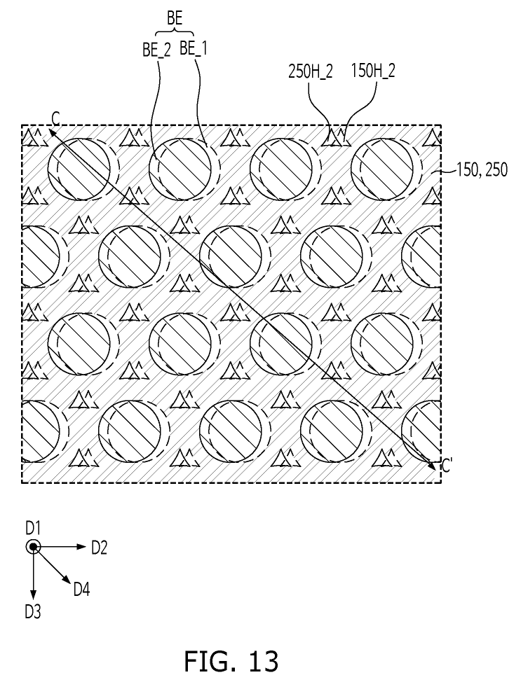

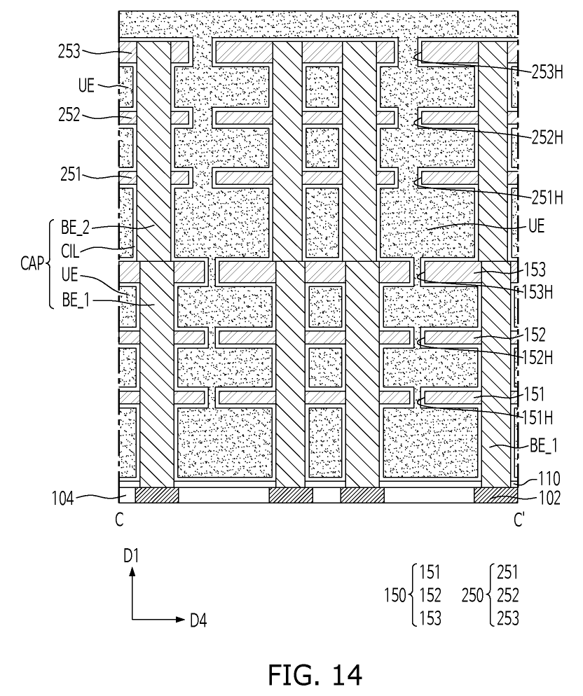

FIG. 11 illustrates a layout of a semiconductor memory device according to some embodiments of the present disclosure. FIGS. 12 and 13 are enlarged views illustrating a part of the semiconductor memory device of FIG. 11. FIG. 14 is a cross-sectional view illustrating the semiconductor memory device taken along line C–C′ of FIG. 12 or FIG. 13. FIGS. 12 and 13 may be or correspond to region R2 of FIG. 11. For convenience, parts different from those described with reference to FIGS. 1-5 will be explained. For example, the parts described with respect to FIGS. 1-5 may also be applied to the embodiments illustrated in FIGS. 11-14 unless context indicates otherwise.

Referring to FIGS. 11, 12, and 14, in a semiconductor memory device according to some embodiments of the present disclosure, the plurality of lower electrodes BE may be arranged in a honeycomb structure.

The lower electrodes BE may be arranged to have a honeycomb structure. For example, the lower electrodes BE may be disposed at centers and vertices of hexagons. For example, six first portions BE_1 of lower electrodes BE may surround and be disposed in the same distance from one first portion BE_1 of a lower electrode BE, and lines connecting centers of the six first portions BE_1 of the lower electrodes BE may form a regular hexagon in a plan view. For example, six second portions BE_2 of lower electrodes BE may surround and be disposed in the same distance from one second portion BE_2 of a lower electrode BE, and lines connecting the six second portions BE_2 of the lower electrodes BE may form a regular hexagon in the plan view. The hexagonal structure in which the lower electrodes BE are disposed may be repeated in the second direction D2 and the third direction D3. For example, the lower electrodes BE may be arranged in a regular hexagonal structure.

The first supporter holes 150H may be spaced apart from each other at a predetermined distance. The second supporter holes 250H may be spaced apart at a predetermined distance. Each of the first supporter holes 150H and the second supporter holes 250H may be arranged to have a honeycomb structure. For example, six first supporter holes 150H may surround and be disposed in the same distance from one first portion BE_1 of a lower electrode BE, and lines connecting centers of the six first supporter holes 150H may form a regular hexagon in a plan view. For example, six second supporter holes 250H may surround and be disposed in the same distance from one second portion BE_2 of a lower electrode BE, and lines connecting the six second supporter holes 250H may form a regular hexagon in the plan view.

Each of the first supporter holes 150H and the second supporter holes 250H may have a rounded closed-curve shape, e.g., in a plan view. For example, each of the first supporter holes 150H and the second supporter holes 250H may have a circular or elliptical shape, e.g., in the plan view. For example, each of the first supporter holes 150H and the second supporter holes 250H may have a circular cylinder shape or an elliptical cylinder shape.

Each of the first supporter holes 150H and the second supporter holes 250H may be disposed at vertices of a regular hexagon such that each of the first portions BE_1 is located at a center of the regular hexagon. Each of the first supporter holes 150H and the second supporter holes 250H may be disposed among three adjacent first portions BE_1.

A distance between a center of each first supporter hole 150H and a center of each of the plurality of first portions BE_1 adjacent to the first supporter hole 150H may be identical. A distance between a center of each second supporter hole 250H and a center of each of the plurality of second portions BE_2 adjacent to the second supporter hole 250H may be identical.

Because the second portions BE_2 of the plurality of lower electrodes BE are offset from the first portions BE_1 of the plurality of lower electrodes BE in the second direction D2, the first supporter holes 150H and the second supporter holes 250H may be offset in the second direction D2.

Referring to FIG. 13, the first supporter holes 150H_2 and the second supporter holes 250H_2 may have shapes different from the first supporter holes 150H and the second supporter holes 250H of FIG. 12. The first supporter holes 150H_2 and the second supporter holes 250H_2 may have a closed-curve shape including apexes/vertices. For example, the first supporter holes 150H_2 and the second supporter holes 250H_2 may have a closed-curve shape composed of three quadrants, e.g., in a plan view. For example, the closed-curve shape of each of the first supporter holes 150H_2 and the second supporter holes 250H_2 in the plan view may be formed by three quadrants/arcs of a circle arranged such that each of the three quadrants/arcs is convex toward a center of the first supporter holes 250H_1 and the second supporter holes 250H_2 and each quadrant/arc contacts the other quadrants/arcs at both ends so that the three quadrants/arcs together form a closed curve. In some embodiments, the first supporter holes 150H_2 and the second supporter holes 250H_2 may have a triangular shape, e.g., in a plan view. For example, each of the first supporter holes 150H_2 and the second supporter holes 250H_2 may have a triangular prism shape.

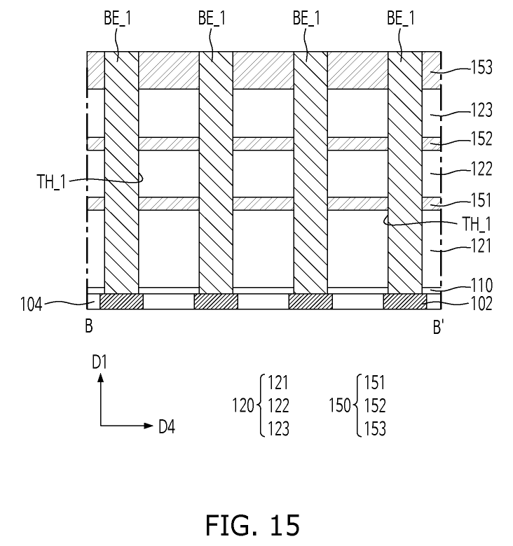

FIGS. 15-21 are cross-sectional views taken along a line corresponding to A–A′ or B–B′ of FIG. 2 or FIG. 3 for explaining a method of manufacturing a semiconductor memory device according to some embodiments of the present disclosure.

Referring to FIG. 15, a plurality of isolation layers 104 and a plurality of conductive patterns 102 may be formed on a substrate, and an etch-stop layer 110 may be formed on the plurality of isolation layers 104 and the plurality of conductive patterns 102. The plurality of isolation layers 104 may be disposed between the plurality of conductive patterns 102. The plurality of isolation layers 104 may electrically isolate the plurality of conductive patterns 102 from each other.

Subsequently, a first mold layer 120 and a first supporter pattern 150 may be formed on the etch-stop layer 110. The first mold layer 120 and the first supporter pattern 150 will be described as each including three layers as examples.

A first-1 mold layer 121, a first-1 supporter layer 151, a first-2 mold layer 122, a first-2 supporter layer 152, a first-3 mold layer 123, and a first-3 supporter layer 153 may be sequentially stacked on the etch-stop layer 110.

Next, a plurality of first through-holes TH_1 penetrating the first mold layer 120 and the first supporter pattern 150 in the first direction D1 may be formed.

The plurality of first through-holes TH_1 may be formed by removing parts of the first mold layer 120 and the first supporter pattern 150 to penetrate the first mold layer 120 and the first supporter pattern 150 in the first direction D1. Each of the plurality of first through-holes TH_1 may have a constant horizontal width, e.g., in the second direction and/or third direction. In some embodiments, each of the plurality of first through-holes TH_1 may have a tapered shape in which a horizontal width becomes narrower in a direction moving from an upper side/end toward a lower side/end of the first through-holes TH_1.

The first through-holes TH_1 may be formed by a dry-etching process in which an etch mask is disposed on the first-3 supporter layer 153 and a portion exposed by the etch mask is removed. For example, the first-3 supporter layer 153, the first-3 mold layer 123, the first-2 supporter layer 152, the first-2 mold layer 122, the first-1 supporter layer 151, and the first-1 mold layer 121 may be sequentially removed, and part of the etch-stop layer 110 may be removed such that the plurality of conductive patterns 102 is exposed.

First portions BE_1 of the plurality of lower electrodes BE may be formed inside the plurality of first through-holes TH_1. The first portions BE_1 may be formed by a process such as CVD, ALD, or PEALD. The first portions BE_1 may include a metal such as Ti, W, Ni, or Co, or a metal nitride such as TiN, TiSiN, TiAlN, TaN, TaSiN, or WN.

After forming the first portions BE_1, a planarization process may be performed. Through the planarization process, part of the first portions BE_1 in upper portions of the first portions BE_1 and the etch mask may be removed. Through the planarization process, an upper surface of the first portions BE_1 and an upper surface of the first-3 supporter layer 153 may become coplanar. Side surfaces of the first portions BE_1 may be covered by or contact the first-3 supporter layer 153.

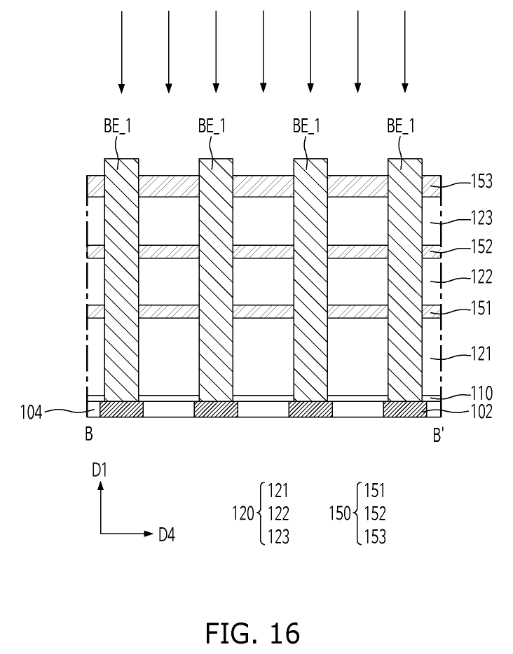

Referring to FIG. 16, a part of the first supporter pattern 150 may be removed such that a part of side surfaces of the first portions BE_1 is exposed. For example, an etch-back process may be performed on the first-3 supporter layer 153. Parts of the first-3 supporter layer 153 may be selectively removed using an etch-selectivity ratio between the first portions BE_1 and the first-3 supporter layer 153.

A thickness of the first-3 supporter layer 153 may decrease by the etch-back process. Here, the thickness of the first-3 supporter layer 153 may be defined as a thickness in the first direction D1. As the thickness of the first-3 supporter layer 153 decreases, parts of side surfaces of the first portions BE_1 may be exposed. For example, parts of the first portions BE_1 may protrude from the first-3 supporter layer 153 in the first direction D1.

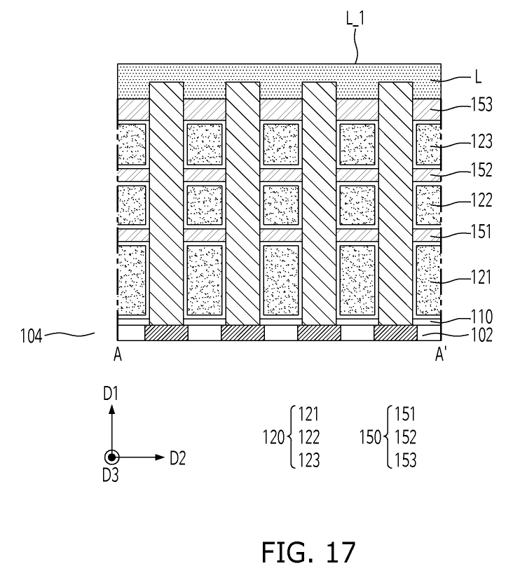

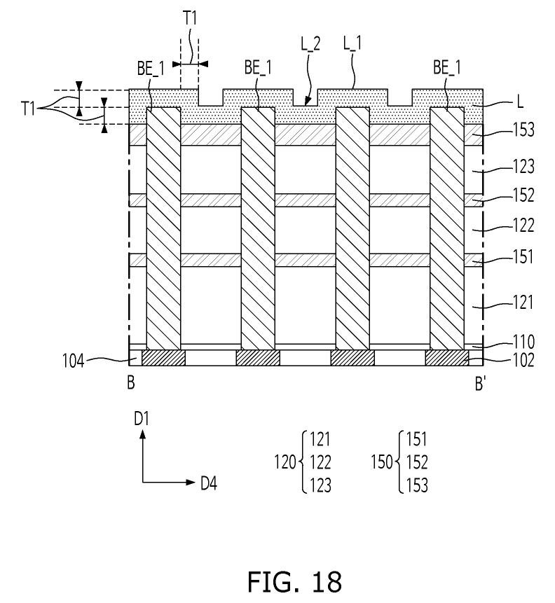

Referring to FIGS. 17 and 18, a liner film L may be formed on the first portions BE_1 and on a remaining part of the first supporter pattern 150.

The liner film L may be conformally formed by an atomic layer deposition method such as ALD or PEALD. For example, the liner film L may be formed on side surfaces and upper surfaces of the pillar-shaped first portions BE_1. The liner film L may include a material having etch-selectivity with respect to the first supporter pattern 150 and the first portions BE_1. For example, the liner film L may include silicon oxide. The liner film L may be formed along a surface of the first-3 supporter layer 153 and along a surface of the first portions BE_1 protruding from the first-3 supporter layer 153. For example, the liner film L may extend along the surfaces of the first-3 supporter layer 153 and the first portions BE_1 with a first thickness T1.

An upper surface L_1 of the liner film L may be spaced by the first thickness T1 from an upper surface of the first portions BE_1. The upper surface L_1 of the liner film L may be perpendicular to the first direction D1. For example, the upper surface L_1 of the liner film L is located at a higher vertical level than the first portions BE_1 and may be defined as a surface perpendicular to the first direction D1.

Portions of the liner film L formed on side surfaces and upper surfaces of the first portions BE_1 adjacent to each other in the second direction D2 and/or the third direction D3 may overlap/merge each other. Portions of the liner film L formed on side surfaces and upper surfaces of the first portions BE_1 adjacent to each other in the fourth direction D4 may be spaced apart from each other. A recessed surface L_2 may be formed between the first portions BE_1 adjacent to each other in the fourth direction D4.

As described above, the liner film L may have the recessed surface L_2 formed between the first portions BE_1. In a plan view, a shape of the recessed surface L_2 may be a two-dimensional figure having an edge line with a closed-curve shape in which four quadrants are symmetrically formed. For example, the closed-curve shape of the edge line of the recessed surface L_2 in the plan view may have a shape of four quadrants/arcs of a circle arranged such that each of the four quadrants/arcs is convex toward a center of the recessed surface L_2 in the plan view and each quadrant/arc contacts adjacent quadrants/arcs at both ends so that the four quadrants/arcs together form a closed curve. A thickness of the liner film L may be smaller than half of a distance between side surfaces of the first portions BE_1 adjacent to each other in the fourth direction D4. The recessed surface L_2 may be defined by a portion of the liner film L disposed on side surfaces of the adjacent first portions BE_1 and a portion of the liner film L disposed on an upper surface of the first-3 supporter layer 153. In some embodiments, a lower surface of the recessed surface L_2 may be located at the same level as an upper surface of the first portions BE_1.

The liner film L may be formed between the first portions BE_1 adjacent to each other in the second direction D2 and/or the third direction D3. A thickness of the liner film L may be greater than half of a distance between side surfaces of the first portions BE_1 adjacent to each other in the second direction D2 and/or the third direction D3. Therefore, no recessed surface may be formed between the first portions BE_1 adjacent to each other in the second direction D2 and/or the third direction D3. For example, the recessed surface may not overlap the first portions BE_1 in the second direction D2 and in the third direction D3.

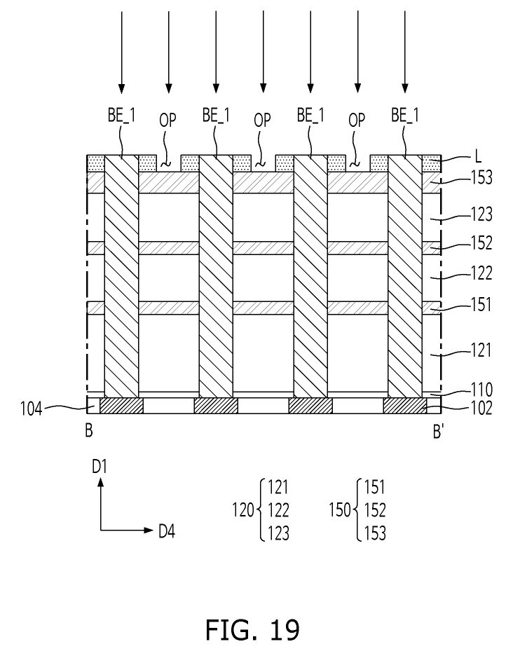

Referring to FIG. 19, part of the liner film L may be removed to form openings OP. Through the openings OP, part of the first supporter pattern 150 may be exposed.

An etch-back process may be performed on the liner film L to expose part of the first supporter pattern 150. The etch-back process may decrease a thickness of the liner film L in the first direction D1. For example, the liner film L may be removed by the first thickness T1 in the first direction D1.

By removing the liner film L by the first thickness T1 from the upper surface L_1 of the liner film L, the upper surfaces of the first portions BE_1 may be exposed. By removing the liner film L by the first thickness T1 from the recessed surface L_2 of the liner film L, the openings OP may be formed. A shape of each opening OP may be identical or substantially identical to a shape of the recessed surface L_2. For example, each opening OP may have a closed-curve shape in which four quadrants are symmetrically formed, e.g., in a plan view. For example, the closed-curve shape of each opening OP in the plan view may have a shape of four quadrants/arcs of a circle arranged such that each of the four quadrants/arcs is convex toward a center of the opening OP in the plan view and each quadrant/arc contacts adjacent quadrants/arcs at both ends so that the four quadrants/arcs together form a closed curve. In some embodiments, the openings OP may have a rounded closed-curve shape formed by an etching process. For example, the openings OP may have a circular or elliptical shape, e.g., in a plan view.

Through the openings OP, an upper surface of the first-3 supporter layer 153 may be exposed. Part of the liner film L may remain on side surfaces of the first portions BE_1. The liner film L on the side surfaces of the first portions BE_1 may have a rounded shape.

In the embodiment of the present disclosure, because the liner film L is formed without using a separate photoresist and/or mask layer, the first supporter pattern 150 can be patterned without a photolithography process.

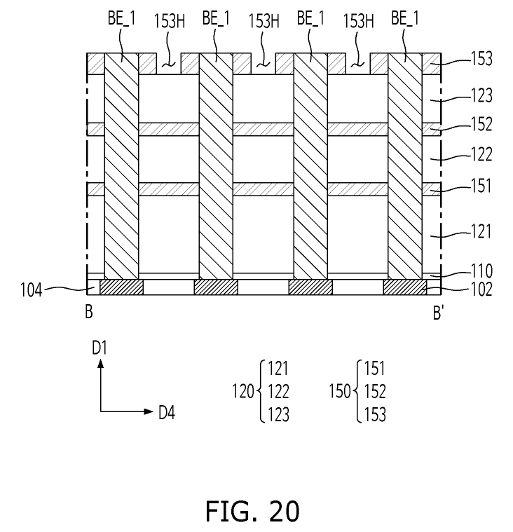

Referring to FIG. 20, part of the first supporter pattern 150 may be removed through the openings OP of the liner film L to form first supporter holes.

The openings OP of the liner film L may expose part of the first-3 supporter layer 153. The part of the first-3 supporter layer 153 exposed through the openings OP of the liner film L may be removed. For example, by a dry-etching process using the liner film L as an etch mask, part of the first-3 supporter layer 153 may be removed to form first supporter holes 153H in the first-3 supporter layer 153.

Because the liner film L has a uniform thickness, the first supporter holes 153H may be located at centers among/between the first portions BE_1, e.g., at a center between each pair of the first portions BE_1 in the fourth direction D4. As described above, the first supporter holes 153H may be formed in the first-3 supporter layer 153. The liner film L may be removed or parts of the first portions BE_1 may remain, e.g., above the first-3 supporter layer 153 in certain embodiments. For example, parts of the first portions BE_1 may protrude from the upper surface of the first-3 supporter layer 153. In some embodiments, the first supporter hole 153H may have a rounded shape.

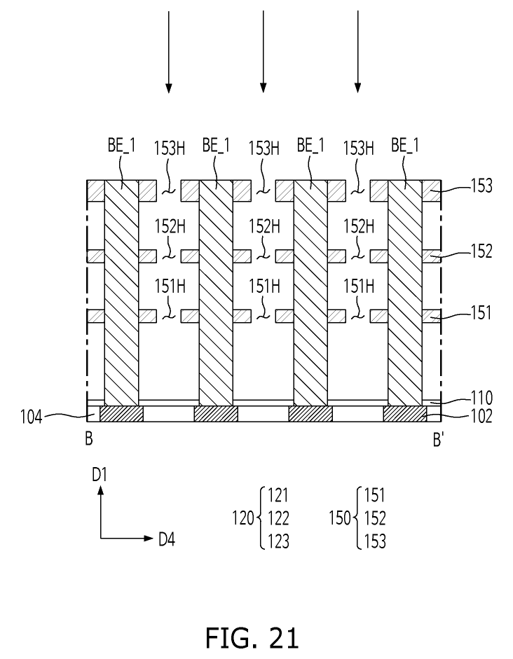

Referring to FIG. 21, the first-3 mold layer 123 may be removed through the first supporter holes 153H. The first-3 mold layer 123 may be removed by a wet-etching process. As the first-3 mold layer 123 is removed by the wet-etching process, the first-2 supporter layer 152 may be exposed.

By repeating such a process, the first-2 supporter hole 152H and the first-1 supporter hole 151H may sequentially be formed. Specifically, by performing a dry-etching process using the first-3 supporter layer 153 as an etch mask, the first-2 supporter hole 152H may be formed in the first-2 supporter layer 152. For example, part of the first-2 supporter layer 152 exposed through the first supporter hole 153H may be removed.

Subsequently, by performing a wet-etching process through the first-2 supporter hole 152H, the first-2 mold layer 122 may be removed, and an upper surface of the first-1 supporter layer 151 may be exposed. By performing a dry-etching process using the first-2 supporter layer 152 and the first-3 supporter layer 153 as etch masks, the first-1 supporter hole 151H may be formed in the first-1 supporter layer 151. For example, part of the first-1 supporter layer 151 exposed through the first-2 supporter hole 152H and the first-3 supporter hole 153H may be removed. By performing a wet-etching process through the first-1 supporter hole 151H, the first-1 mold layer 121 may be removed, and the etch-stop layer 110 may be exposed.

Because the first-2 supporter hole 152H is formed by performing the dry-etching process through the first-3 supporter hole 153H, the first-2 supporter hole 152H may be formed at a position aligned with the first-3 supporter hole 153H in the first direction D1. Further, because the first-1 supporter hole 151H is formed by performing the dry-etching process through the first-2 supporter hole 152H and the first-3 supporter hole 153H, the first-1 supporter hole 151H may be formed at a position aligned with the first-2 supporter hole 152H and the first-3 supporter hole 153H in the first direction D1. For example, the first to third supporter holes 151H, 152H, and 153H may vertically overlap each other.

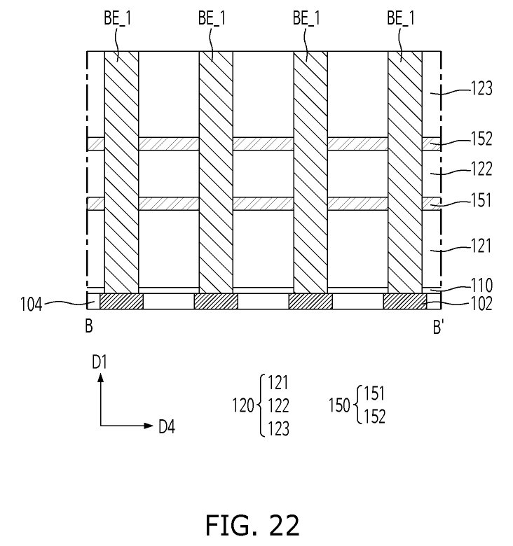

FIGS. 22-26 are cross-sectional views taken along a line corresponding to B–B′ of FIG. 2 or FIG. 3 for explaining a method of manufacturing a semiconductor memory device according to some embodiments of the present disclosure. For convenience, parts different from those described with reference to FIGS. 15-21 will be explained. For example, the parts described with respect to FIGS. 15-21 may also be applied to the present embodiments unless contexts indicate otherwise.

Referring to FIG. 22, the first mold layer 120 and the first supporter pattern 150 may be formed on the etch-stop layer. For example, the first-1 mold layer 121, the first-1 supporter layer 151, the first-2 mold layer 122, the first-2 supporter layer 152, and the first-3 mold layer 123 may be sequentially stacked on the etch-stop layer 110.

Subsequently, a plurality of first through-holes penetrating the first mold layer 120 and the first supporter pattern 150 in the first direction D1 may be formed similarly to the through-holes shown in FIG. 15.

The first through-holes may be formed by a dry-etching process in which an etch mask is disposed on the first-3 mold layer 123 and a portion exposed by the etch mask is removed. For example, the first-3 mold layer 123, the first-2 supporter layer 152, the first-2 mold layer 122, the first-1 supporter layer 151, and the first-1 mold layer 121 may be sequentially removed, and part of the etch-stop layer 110 may be removed such that the plurality of conductive patterns 102 is exposed.

Next, the first portions BE_1 of the plurality of lower electrodes BE may be formed inside the plurality of first through-holes. After forming the first portions BE_1, a planarization process may be performed. Through the planarization process, part of the first portions BE_1 in upper portions of the first portions BE_1 and the etch mask may be removed. Through the planarization process, an upper surface of the first portions BE_1 and an upper surface of the first-3 mold layer 123 may become coplanar. Side surfaces of the first portions BE_1 may be covered by the first-3 mold layer 123.

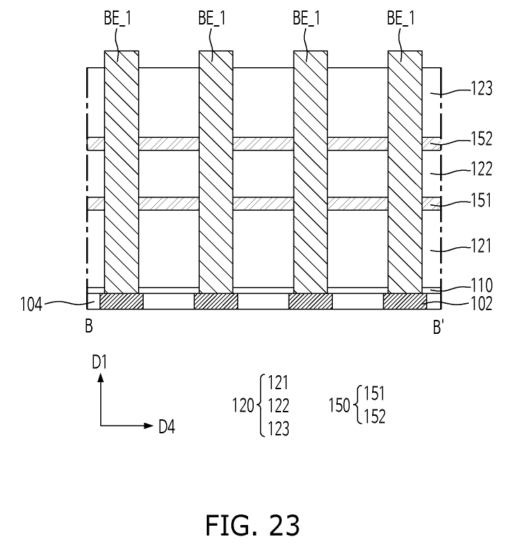

Referring to FIG. 23, part of the first mold layer 120 may be removed such that part of side surfaces of the first portions BE_1 is exposed. For example, an etch-back process may be performed on the first-3 mold layer 123. Parts of the first-3 mold layer 123 may be selectively removed using an etch-selectivity ratio between the first portions BE_1 and the first-3 mold layer 123.

A thickness of the first-3 mold layer 123 may decrease by the etch-back process. Here, the thickness of the first-3 mold layer 123 may be defined as a thickness in the first direction D1. As the thickness of the first-3 mold layer 123 decreases, parts of side surfaces of the first portions BE_1 may be exposed. For example, parts of the first portions BE_1 may protrude from the first-3 mold layer 123 in the first direction D1.

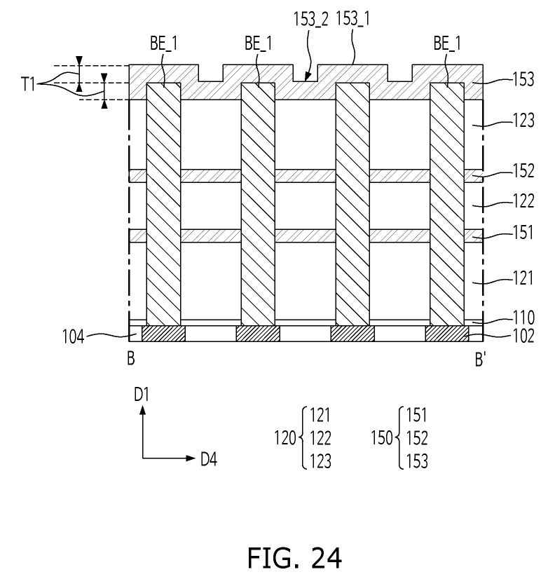

Referring to FIG. 24, the first-3 supporter layer 153 may be formed on the exposed first portions BE_1 and on a remaining part of the first mold layer 120.

The first-3 supporter layer 153 may be conformally formed by an atomic layer deposition method such as ALD or PEALD. The first-3 supporter layer 153 may include the same material as the first supporter pattern 150 (e.g., the first-1 supporter layer 151 and the first-2 supporter layer 152). The first-3 supporter layer 153 may include a material having etch-selectivity with respect to the first mold layer 120 and the first portions BE_1. For example, the first-3 supporter layer 153 may include at least one of silicon oxynitride (SiON), silicon nitride (SiN), silicon carbon nitride (SiCN), or tantalum oxide (TaO). The first-3 supporter layer 153 may be formed along a surface of the first-3 mold layer 123 and along a surface of the first portions BE_1 protruding from the first-3 mold layer 123. For example, the first-3 supporter layer 153 may extend along the surfaces of the first-3 mold layer 123 and the first portions BE_1 with the first thickness T1.

Portions of the first-3 supporter layer 153 formed on side surfaces and upper surfaces of the first portions BE_1 adjacent to each other in the fourth direction D4 may be spaced apart from each other. A recessed surface 153_2 may be formed among/between the first portions BE_1 adjacent to each other in the fourth direction D4. In a plan view, a shape of the recessed surface 153_2 may be a two-dimensional figure having an edge line with a closed-curve shape in which four quadrants are symmetrically formed. For example, the closed-curve shape of the edge line of the recessed surface 153_2 in the plan view may have a shape of four quadrants/arcs of a circle arranged such that each of the four quadrants/arcs is convex toward a center of the recessed surface 153_2 in the plan view and each quadrant/arc contacts adjacent quadrants/arcs at both ends so that the four quadrants/arcs together form a closed curve.

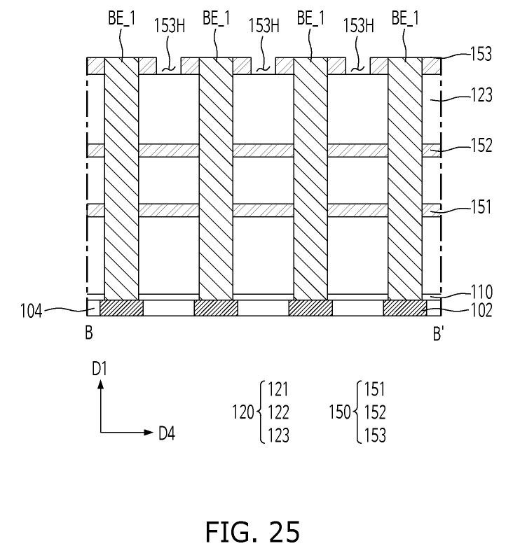

Referring to FIG. 25, part of the first-3 supporter layer 153 may be removed to form first supporter holes 153H. For example, an etch-back process may be performed on the first-3 supporter layer 153. The etch-back process may decrease a thickness of the first-3 supporter layer 153 in the first direction D1. For example, the first-3 supporter layer 153 may be removed by the first thickness T1 in the first direction D1.

By removing the first-3 supporter layer 153 by the first thickness T1 from an upper surface 153_1 of the first-3 supporter layer 153, upper surfaces of the first portions BE_1 may be exposed. By removing the first-3 supporter layer 153 by the first thickness T1 from the recessed surface 153_2 of the first-3 supporter layer 153, the first supporter holes 153H may be formed. Through the first supporter holes 153H, an upper surface of the first-3 mold layer 123 may be exposed. In some embodiments, a side surface of the first-3 supporter layer 153 may have a rounded shape.

In the embodiment of the present disclosure, because the first-3 supporter layer 153 is formed without using a separate photoresist and/or mask layer, the first supporter pattern 150 can be patterned without a photolithography process.

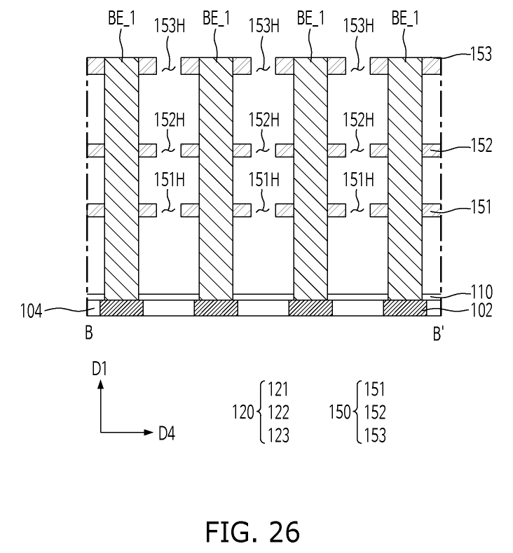

Referring to FIG. 26, the first mold layer 120 may be removed through the first supporter holes 151H, 152H, and 153H, and the first-2 supporter hole 152H and the first-1 supporter hole 151H may be formed as described below.

The first-3 mold layer 123 may be removed through the first supporter holes 153H. The first-3 mold layer 123 may be removed by a wet-etching process. As the first-3 mold layer 123 is removed by the wet-etching process, an upper surface of the first-2 supporter layer 152 may be exposed.

Subsequently, a first-2 supporter hole 152H may be formed in the first-2 supporter layer 152 using a dry etching process. Through the first-2 supporter hole 152H, the first-2 mold layer 122 may be removed, and a first-1 supporter hole 151H may be formed in the first-1 supporter layer 151, and then the first-1 mold layer 121 may be removed through the first-1 supporter hole 151H.

According to the manufacturing method of the embodiment, because the first-3 supporter layer 153 is formed after forming the first portions BE_1, a length of the first portions BE_1 in the first direction D1 can be increased. For example, the length of the first portions BE_1 in the first direction D1 can be increased by the first thickness T1. Accordingly, a semiconductor memory device including a capacitor structure having improved capacitance can be manufactured, e.g., with less manufacturing cost.

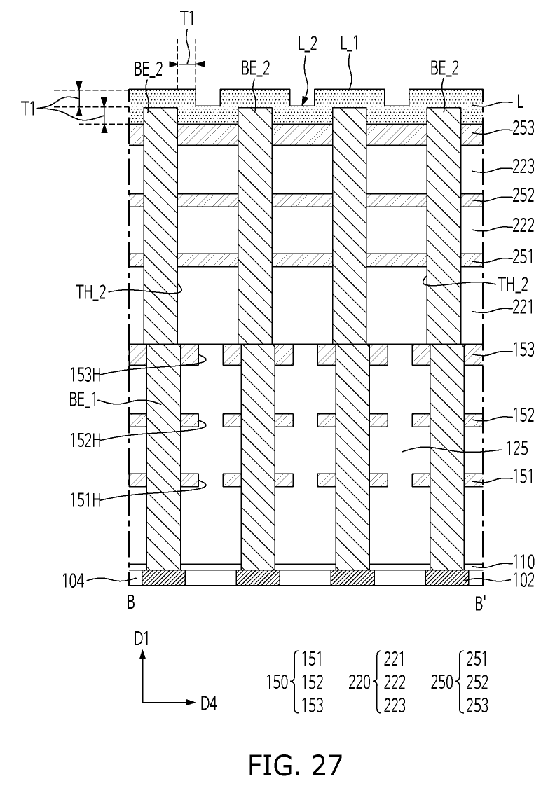

FIGS. 27-29 are cross-sectional views taken along a line corresponding to B–B′ of FIG. 2 or FIG. 3 for explaining a method of manufacturing a semiconductor memory device according to some embodiments of the present disclosure.

Referring to FIG. 27, a sacrificial layer 125 may be filled through the first supporter holes 151H, 152H, and 153H. For example, the sacrificial layer 125 may include silicon oxide. The sacrificial layer 125 may be disposed on side surfaces of the first portions BE_1 and on a surface of the first supporter pattern 150. An upper surface of the sacrificial layer 125 may be coplanar with an upper surface of the first-3 supporter layer 153 and an upper surface of the first portions BE_1. After forming the sacrificial layer 125, a planarization process may be performed.

The second mold layer 220 and the second supporter pattern 250 may be formed on the first portions BE_1 and the first-3 supporter layer 153. The second mold layer 220 and the second supporter pattern 250 will be described as each including three layers. For example, a second-1 mold layer 221, a second-1 supporter layer 251, a second-2 mold layer 222, a second-2 supporter layer 252, a second-3 mold layer 223, and a second-3 supporter layer 253 may be sequentially stacked on the first portions BE_1 and the first-3 supporter layer 153.

Subsequently, a plurality of second through-holes TH_2 penetrating the second mold layer 220 and the second supporter pattern 250 in the first direction D1 may be formed. A method of forming the plurality of second through-holes TH_2 may be identical or substantially identical to a method of forming the plurality of first through-holes TH_1.

The plurality of second through-holes TH_2 may be misaligned with the plurality of first through-holes TH_1. The plurality of second through-holes TH_2 may at least partly overlap the plurality of first through-holes TH_1 in the first direction D1 and may be offset in the second direction D2.

Second portions BE_2 of the plurality of lower electrodes BE may be formed inside the plurality of second through-holes TH_2. The second portions BE_2 may be formed by a process such as CVD, ALD, or PEALD. The second portions BE_2 may include the same material as the first portions BE_1. For example, the second portions BE_2 may include a metal such as Ti, W, Ni, or Co, or a metal nitride such as TiN, TiSiN, TiAlN, TaN, TaSiN, or WN.

Next, after forming the second portions BE_2, a planarization process may be performed. Through the planarization process, an upper surface of the second portions BE_2 and an upper surface of the second-3 supporter layer 253 may become coplanar. Side surfaces of the second portions BE_2 may be covered by or contact the second-3 supporter layer 253.

Part of the second supporter pattern 250 may be removed such that part of side surfaces of the second portions BE_2 is exposed. For example, an etch-back process may be performed on the second-3 supporter layer 253. The second-3 supporter layer 253 may be selectively removed using an etch-selectivity ratio between the second portions BE_2 and the second-3 supporter layer 253.

A thickness of the second-3 supporter layer 253 may decrease by the etch-back process. Here, the thickness of the second-3 supporter layer 253 may be defined as a thickness in the first direction D1. As the thickness of the second-3 supporter layer 253 decreases, parts of side surfaces of the second portions BE_2 may be exposed. For example, parts of the second portions BE_2 may protrude from the second-3 supporter layer 253 in the first direction D1.

A liner film L may be formed on the protruding second portions BE_2 and on a remaining part of the second supporter pattern 250.

The liner film L may be conformally formed by an atomic layer deposition method such as ALD or PEALD. The liner film L may include a material having etch-selectivity with respect to the second supporter pattern 250 and the second portions BE_2. For example, the liner film L may include silicon oxide. The liner film L may be formed along a surface of the second-3 supporter layer 253 and along a surface of the second portions BE_2 protruding from the second-3 supporter layer 253. For example, the liner film L may extend along the surfaces of the second-3 supporter layer 253 and the second portions BE_2 with the first thickness T1.

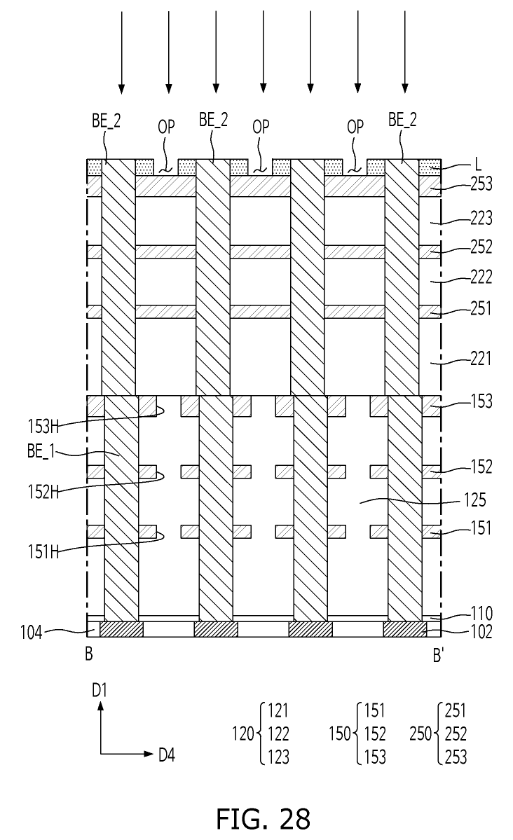

Referring to FIG. 28, part of the liner film L may be removed to form openings OP. Through the openings OP, part of the second supporter pattern 250 may be exposed.

To expose part of the second supporter pattern 250, an etch-back process may be performed on the liner film L. The etch-back process may decrease a thickness of the liner film L in the first direction D1.

By removing the liner film L by the first thickness T1 from the upper surface L_1 of the liner film L, upper surfaces of the second portions BE_2 may be exposed. By removing the liner film L by the first thickness T1 from the recessed surface L_2 of the liner film L, the openings OP may be formed. Through the openings OP, an upper surface of the second-3 supporter layer 253 may be exposed. Part of the liner film L may remain on side surfaces of the second portions BE_2. The liner film L on the side surfaces of the second portions BE_2 may have a rounded shape.

In the embodiment of the present disclosure, because the liner film L is formed without using a separate photoresist and/or mask layer, the second supporter pattern 250 may be patterned without a photolithography process. In some embodiments, the second supporter pattern 250 may be patterned by forming no liner film and using a photoresist and/or mask layer.

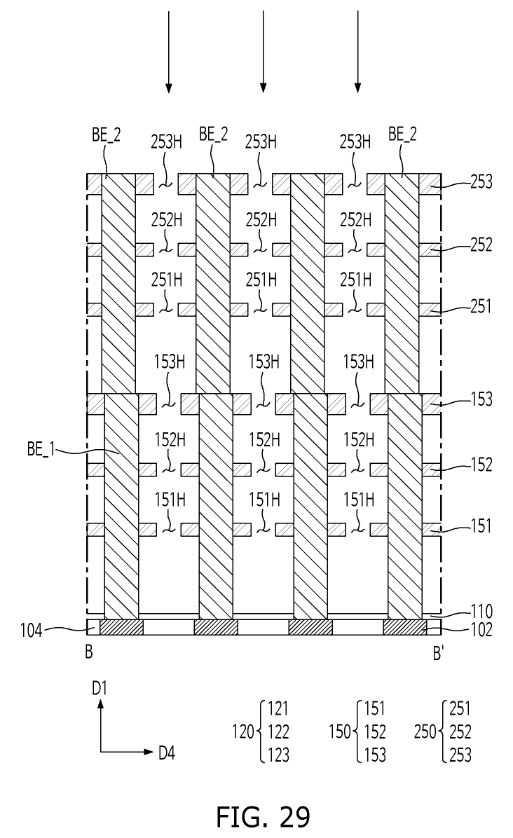

Referring to FIG. 29, part of the second supporter pattern 250 may be removed through the openings OP of the liner film L to form second supporter holes.

The openings OP of the liner film L may expose part of the second-3 supporter layer 253. The part of the second-3 supporter layer 253 exposed through the openings OP of the liner film L may be removed. For example, by a dry-etching process using the liner film L as an etch mask, part of the second-3 supporter layer 253 may be removed to form second supporter holes 253H in the second-3 supporter layer 253. Because the liner film L has a uniform thickness, the second supporter holes 253H may be located at centers among the second portions BE_2. As described above, the second supporter holes 253H may be formed in the second-3 supporter layer 253. The liner film L may be removed or parts of the second portions BE_2 may remain above the second-3 supporter layer 253. For example, parts of the second portions BE_2 may protrude from an upper surface of the second-3 supporter layer 253 in certain embodiments. In some embodiments, each second supporter hole 253H may have a rounded shape.

The second-3 mold layer 223 may be removed through the second supporter holes 253H. The second-3 mold layer 223 may be removed by a wet-etching process. As the second-3 mold layer 223 is removed by the wet-etching process, the second-2 supporter layer 252 may be exposed. Thereafter, the second-2 supporter hole 252H may be formed by a dry-etching process, and the second-2 mold layer 222 may be removed by a wet-etching process. By repeating the process, the second-1 supporter hole 251H may be formed, and the second-1 mold layer 221 and the sacrificial layer 125 may be removed by a wet-etching process.

Thereafter, the dielectric layer CIL and the upper electrode UE may be sequentially deposited through the first supporter holes 151H, 152H, 153H and the second supporter holes 251H, 252H, 253H to form the capacitor structure.

Although the invention has been described with reference to limited embodiments and drawings, the invention is not limited thereto, and various modifications and alterations can be made by those of ordinary skill in the art without departing from the spirit of the invention and within the scope of equivalency of the patent claims described below.

1. A semiconductor memory device comprising:
a substrate;
a plurality of lower electrodes each comprising a first portion on the substrate and extending in a first direction perpendicular to an upper surface of the substrate, and a second portion stacked on the first portion and extending in the first direction;
a first supporter pattern surrounding a sidewall of the first portion of each of the plurality of lower electrodes and comprising a plurality of first supporter holes;
a second supporter pattern surrounding a sidewall of the second portion of each of the plurality of lower electrodes and comprising a plurality of second supporter holes;
a dielectric layer on the plurality of lower electrodes, the first supporter pattern, and the second supporter pattern; and
an upper electrode covering the dielectric layer,
wherein the second portion overlaps part of the first portion in the first direction and is offset from the first portion in a second direction perpendicular to the first direction.

2. The semiconductor memory device of claim 1, wherein each of the plurality of second supporter holes is offset from each of the plurality of first supporter holes in the second direction.

3. The semiconductor memory device of claim 1, wherein each of the plurality of first supporter holes is located between first portions of the plurality of lower electrodes adjacent to corresponding one of the plurality of first supporter holes, and
each of the plurality of second supporter holes is located between second portions of the plurality of lower electrodes adjacent to corresponding one of the plurality of second supporter holes.

4. The semiconductor memory device of claim 3, wherein, in a plan view, a distance between a center of each of the plurality of first supporter holes and a center of each first portion of the plurality of lower electrodes adjacent to corresponding one of the plurality of first supporter holes is identical, and
a distance between a center of each of the plurality of second supporter holes and a center of each second portion of the plurality of lower electrodes adjacent to corresponding one of the plurality of second supporter holes is identical.

5. The semiconductor memory device of claim 2, wherein, in a plan view, each of the plurality of first supporter holes and the plurality of second supporter holes has a circular shape.

6. The semiconductor memory device of claim 1, wherein a topmost portion of the first supporter pattern is located at a same vertical level as a topmost portion of the first portion of each of the plurality of lower electrodes, and
a topmost portion of the second supporter pattern is located at a same vertical level as a topmost portion of the second portion of each of the plurality of lower electrodes.

7. The semiconductor memory device of claim 1, wherein a topmost portion of the first portion of each of the plurality of lower electrodes is located at a higher vertical level than a topmost portion of the first supporter pattern.

8. The semiconductor memory device of claim 1, wherein the first supporter pattern comprises a first curved portion, and
the first curved portion is convex toward the second supporter pattern.

9. The semiconductor memory device of claim 8, wherein the second supporter pattern comprises a second curved portion, and
the second curved portion is convex in a direction away from the first supporter pattern.

10. The semiconductor memory device of claim 1, wherein each of the plurality of lower electrodes has a pillar shape.

11. The semiconductor memory device of claim 1, wherein each of the first supporter pattern and the second supporter pattern further comprises a plurality of first supporter layers and a plurality of second supporter layers located at different vertical levels, and
the plurality of first supporter layers comprises first supporter holes aligned in the first direction, and the plurality of second supporter layers comprises second supporter holes aligned in the first direction.

12. The semiconductor memory device of claim 11, wherein the first supporter holes are offset from the second supporter holes in the second direction.

13. The semiconductor memory device of claim 11, wherein the plurality of first supporter layers comprises a first-1 supporter layer, a first-2 supporter layer located at a higher vertical level than the first-1 supporter layer, and a first-3 supporter layer located at a higher vertical level than the first-2 supporter layer;
the plurality of second supporter layers comprises a second-1 supporter layer, a second-2 supporter layer located at a higher vertical level than the second-1 supporter layer, and a second-3 supporter layer located at a higher vertical level than the second-2 supporter layer;
an upper surface of the first-3 supporter layer is located at the same vertical level as an upper surface of the first portion of each of the plurality of lower electrodes; and
an upper surface of the second-3 supporter layer is located at the same vertical level as an upper surface of the second portion of each of the plurality of lower electrodes.

14. The semiconductor memory device of claim 1, wherein, in a plan view, first portions of the plurality of lower electrodes are arranged to have a first grid pattern in which the first portions are spaced apart by a first pitch in the second direction and in a third direction perpendicular to the first direction and the second direction, and
wherein the plurality of first supporter holes is arranged to have a second grid pattern in which each of the plurality of first supporter holes is spaced apart from adjacent first supporter holes by the first pitch in the second direction and the third direction and is disposed at a center among four adjacent first portions of the plurality of lower electrodes.

15. The semiconductor memory device of claim 1, wherein first portions of the plurality of lower electrodes are arranged in a honeycomb structure, with each first portion located at the center and vertices of hexagons, and
wherein each of the plurality of first supporter holes is disposed at a center among three adjacent first portions of the plurality of lower electrodes.

16. A semiconductor memory device comprising:
a substrate including an active pattern;
a plurality of conductive patterns disposed on the active pattern;
a plurality of lower electrodes respectively electrically connected to the plurality of conductive patterns;
a plurality of supporter patterns supporting the plurality of lower electrodes,
a dielectric layer on the plurality of lower electrodes and the plurality of supporter patterns; and
an upper electrode covering the dielectric layer,
wherein each of the plurality of lower electrodes comprises:
a first portion extending in a first direction perpendicular to an upper surface of the substrate; and
a second portion stacked on the first portion and extending in the first direction,
wherein the plurality of supporter patterns comprises:
a first supporter pattern surrounding a sidewall of the first portion and comprising a plurality of first supporter holes; and
a second supporter pattern surrounding a sidewall of the second portion and comprising a plurality of second supporter holes,
wherein each second portion overlaps part of a corresponding first portion in the first direction and is offset from the first portion by a first distance in a second direction perpendicular to the first direction, and
wherein each of the plurality of second supporter holes is offset from a corresponding one of the plurality of first supporter holes by the first distance in the second direction.

17. The semiconductor memory device of claim 16, wherein a topmost surface of the first supporter pattern contacts a bottommost surface of the second portion.

18. The semiconductor memory device of claim 16, wherein, in a plan view, a plurality of first portions are arranged to form a grid pattern in which the first portions are spaced apart by a constant interval along the second direction and a third direction perpendicular to the first and the second directions, and
wherein the plurality of first portions and the plurality of first supporter holes are alternately arranged along a fourth direction that forms predetermined angles with each of the second direction and the third direction.

19. The semiconductor memory device of claim 18, wherein each of the plurality of first supporter holes is spaced apart from the first portions of the plurality of lower electrodes adjacent to corresponding one of the plurality of first supporter holes in the fourth direction.

20. A semiconductor memory device comprising:
a substrate;
a plurality of lower electrodes each comprising a first portion on the substrate and extending in a first direction perpendicular to an upper surface of the substrate, and a second portion stacked on the first portion and extending in the first direction;
a first supporter pattern comprising a plurality of first supporter layers in which a first supporter-hole pattern including a plurality of first supporter holes aligned and spaced in the first direction is formed, the first supporter pattern surrounding a sidewall of the first portion of each of the plurality of lower electrodes;
a second supporter pattern comprising a plurality of second supporter layers in which a second supporter-hole pattern including a plurality of second supporter holes aligned and spaced in the first direction is formed, the second supporter pattern surrounding a sidewall of the second portion of each of the plurality of lower electrodes;
a dielectric layer on the plurality of lower electrodes, the first supporter pattern, and the second supporter pattern; and
an upper electrode on the dielectric layer,
wherein the second portion overlaps part of the first portion in the first direction,
the second portion is offset from the first portion in a second direction perpendicular to the first direction, and
the first supporter-hole pattern and the second supporter-hole pattern are offset in the second direction.
